(19) United States
(12) Patent Application Publication
(10) Pub. No.: US 2026/0143667 A1
(43) Pub. Date: May 21, 2026

(54) SEMICONDUCTOR DEVICE AND METHOD FOR MANUFACTURING THE SAME

(71) Applicant: SK hynix Inc., Gyeonggi-do (KR)

(72) Inventors: Jun Hwe CHA, Gyeonggi-do (KR); Wha Young KIM, Gyeonggi-do (KR)

(21) Appl. No.: 19/358,431

(22) Filed: Oct. 15, 2025

(30) Foreign Application Priority Data
Nov. 19, 2024 (KR) 10-2024-0165698

(51) Int. Cl. H10B 12/00; G11C 5/06; H10D 30/60

(52) U.S. Cl. CPC H10B 12/00; G11C 5/063; H10B 12/01; H10D 30/611

(57) ABSTRACT

A semiconductor device includes a first bitline extending in a first direction, a first wordline extending in a second direction crossing the first direction, a first active region contacting the first bitline, a back-gate extending parallel to the first wordline, and a storage transistor contacting the first active region. The first active region is disposed between the first wordline and the back-gate, and includes a vertical portion extending in a third direction crossing the first and second directions and a horizontal portion that contacts one end of the vertical portion and the first bitline.

### CROSS-REFERENCE TO RELATED APPLICATION

This patent application claims the priority and benefits of Korean patent application No. 10-2024-0165698, filed on Nov. 19, 2024, the disclosure of which is incorporated herein by reference in its entirety.

### TECHNICAL FIELD

The technology and embodiments of the present disclosure generally relate to a semiconductor device, and more particularly to a semiconductor device including memory cells.

### BACKGROUND

As miniaturization and higher degrees of integration of semiconductor devices have become major issues, memory cells included in semiconductor devices may be formed to have three-dimensional (3D) patterns. Miniaturized memory cells with three-dimensional (3D) patterns may be equipped with configurations that improve operation characteristics of the memory cells.

### SUMMARY

Various embodiments of the present disclosure relate to a 3D semiconductor memory device (referred to simply also as a semiconductor device) having a higher degree of integration while including two transistors.

Various embodiments of the present disclosure relate to a semiconductor memory device configured to perform a multiply-accumulate (MAC) operation.

In accordance with an embodiment of the present disclosure, a semiconductor device may include a first bitline extending in a first direction; a first wordline extending in a second direction crossing the first direction; a first active region contacting the first bitline; a back-gate extending parallel to the first wordline; and a storage transistor contacting the first active region, wherein the first active region is disposed between the first wordline and the back-gate, and includes a vertical portion extending in a third direction crossing the first and second directions and a horizontal portion that contacts one end of the vertical portion and the first bitline.

In an embodiment, the storage transistor may include a storage gate formed to contact another end of the vertical portion; a storage gate insulation layer formed to overlap with the storage gate; and a second active region formed to overlap with the storage gate insulation layer.

In an embodiment, the semiconductor device may further include a second bitline extending in the first direction and contacting the second active region; and a second wordline extending in the first direction and contacting the second active region.

In an embodiment, the second bitline may be formed to contact a plurality of second active regions arranged parallel to each other in the first direction; and the second wordline may be formed to contact a plurality of second active regions arranged parallel to each other in the first direction.

In an embodiment, the semiconductor device may further include an isolation insulation layer disposed between the second bitline and the second wordline and extending in the first direction.

In an embodiment, the storage gate may include a trench region that is disposed in the storage gate and extends in the third direction from one surface of the storage gate toward another other surface facing or opposite to the one surface. The storage gate insulation layer may be formed to overlap a sidewall and a bottom surface of the trench region. The second active region may be formed to overlap with the gate insulation layer.

In an embodiment, the storage transistor may include a storage gate formed to contact another end of the vertical portion; a storage gate insulation layer formed to surround a sidewall of the storage gate; and a second active region formed to surround the storage gate insulation layer, wherein the second active region contacts a second bitline extending in the first direction and a second wordline extending in the second direction.

In an embodiment, at least a portion of the second bitline may be formed to overlap with the second wordline.

In an embodiment, the semiconductor device may further include an isolation insulation layer disposed over the second bitline, wherein the second wordline is disposed over the isolation insulation layer.

In an embodiment, the second bitline may be formed to contact a plurality of second active regions arranged parallel to each other in the first direction.

In an embodiment, the second wordline may be formed to contact a plurality of second active regions arranged parallel to each other in the second direction.

In an embodiment, the second wordline may be formed to surround at least a portion of the second active region.

In an embodiment, the second bitline may be formed to surround at least a portion of the second active region.

In accordance with an embodiment of the present disclosure, a method for manufacturing a semiconductor device may include forming a first bitline extending in a first direction over a substrate; forming a back-gate extending in a second direction crossing the first direction over the first bitline; forming a first active region contacting the first bitline; forming a first wordline extending in the second direction on the first bitline; and forming a storage transistor contacting the first active region, wherein the first active region is disposed between the first wordline and the back-gate, and includes a vertical portion extending in a third direction crossing the first and second directions and a horizontal portion contacting one end of the vertical portion and the first bitline.

In an embodiment, forming the storage transistor may include forming a storage gate contacting another end of the vertical portion; forming a trench region that is disposed in the storage gate and extends in the third direction from one surface of the storage gate toward another surface facing or opposite to the one surface; forming a storage gate insulation layer that overlaps with bottom and side surfaces of the trench region; and forming a second active region that overlaps with the storage gate insulation layer.

In an embodiment, the method may further include forming an isolation insulation layer on the second active region; forming a second bitline contacting the second active region within the isolation insulation layer; and forming a second wordline that is isolated from the second bitline by the isolation insulation layer, wherein the second bitline and the second wordline are formed to extend in the first direction.

In an embodiment, forming the storage transistor may include forming a storage gate contacting another end of the vertical portion; forming a storage gate insulation layer surrounding a sidewall of the storage gate; and forming a second active region surrounding the storage gate insulation layer.

In an embodiment, the method may further include forming a second bitline that extends in the first direction and surrounds at least a portion of the second active region; forming an isolation insulation layer disposed over the second bitline; and forming a second wordline that extends in the second direction and surrounds at least a portion of the second active region, wherein the second bitline is formed to overlap with at least a portion of the second wordline.

In accordance with an embodiment of the present disclosure, a semiconductor device may include a write bitline extending in a first direction; a write wordline extending in a second direction crossing the first direction; a back-gate extending parallel to the write wordline; a first active region that contacts the write bitline and extends between the write wordline and the back-gate; a storage transistor contacting the first active region; a read bitline extending in the first direction; and a read wordline extending in the first direction, wherein the storage transistor includes a storage gate that contacts the first active region and includes a trench region; a storage gate insulation layer that overlaps with a sidewall and a bottom surface of the trench region; and a second active region that overlaps with the storage gate insulation layer, wherein the second active region contacts the read bitline and the read wordline.

In accordance with another embodiment of the present disclosure, a semiconductor device may include a write bitline extending in a first direction; a write wordline extending in a second direction crossing the first direction; a back-gate extending parallel to the write wordline; a first active region that contacts the write bitline and extends between the write wordline and the back-gate; a storage transistor contacting the first active region; a read bitline extending in the first direction; and a read wordline extending in the second direction, wherein the storage transistor includes: a pillar-shaped storage gate that contacts the first active region; a storage gate insulation layer that surrounds a sidewall of the storage gate; and a second active region that surrounds the storage gate insulation layer, wherein the second active region contacts the read bitline and the read wordline.

It is to be understood that both the foregoing general description and the following detailed description of the present disclosure are illustrative and descriptive, and intended to provide further description of the embodiments of the present disclosure as claimed.

### BRIEF DESCRIPTION OF THE DRAWINGS

The above and other features and beneficial aspects of the embodiments of the present disclosure will become readily apparent with reference to the following detailed description when considered in conjunction with the accompanying drawings.

FIG. 1A is a cross-sectional view illustrating a portion of a semiconductor device according to an embodiment of the present disclosure.

FIG. 1B is a cross-sectional view illustrating a configuration of the semiconductor device taken along the first cutting line (A1-A1′) of FIG. 1A according to an embodiment of the present disclosure.

FIG. 2 is a circuit diagram illustrating a memory cell array of the semiconductor device according to an embodiment of the present disclosure.

FIG. 3A is a diagram illustrating a portion of a semiconductor device according to another embodiment of the present disclosure.

FIG. 3B is a cross-sectional view illustrating a configuration of the semiconductor device taken along the second cutting line (A2-A2′) of FIG. 3A according to another embodiment of the present disclosure.

FIG. 4 is a circuit diagram illustrating a connection relationship between a read bitline and a read wordline of a semiconductor device according to another embodiment of the present disclosure.

FIGS. 5A to 15B are diagrams illustrating a method for manufacturing the semiconductor device according to an embodiment of the present disclosure.

FIGS. 16A to 26B are diagrams illustrating a method for manufacturing the semiconductor device according to another embodiment of the present disclosure.

### DETAILED DESCRIPTION

This present disclosure provides embodiments of a semiconductor device including memory cells that may be used in configurations to substantially address one or more technical or engineering issues and to mitigate limitations or disadvantages encountered in some other semiconductor devices. Some embodiments of the present disclosure relate to a semiconductor memory device having a higher degree of integration while including two transistors. Some embodiments of the present disclosure relate to a semiconductor memory device that performs a multiply-accumulate (MAC) operation. In recognition of the issues above, the present disclosure may provide the semiconductor device that includes a channel region having a vertical portion, resulting in a higher degree of integration of the semiconductor device. The present disclosure may provide the semiconductor device that performs a multiply-accumulate (MAC) operation while having a storage transistor.

Reference will now be made in detail to the embodiments of the present disclosure which are illustrated in the accompanying drawings. Wherever possible, the same reference numbers will be used throughout the drawings to refer to the same or like parts. While the embodiments of the present disclosure are susceptible to various modifications and alternative forms, specific embodiments thereof are shown in the drawings. However, the embodiments should not be construed as being limited to the embodiments set forth herein but include various modifications, equivalents and/or alternatives of the embodiments. The embodiments of the present disclosure may provide a variety of advantageous effects capable of being directly or indirectly recognized by one of ordinary skill in the art.

In the following description, a detailed description of related known configurations or functions incorporated herein will be omitted to avoid obscuring the subject matter.

The terminology used herein is for the purpose of describing particular embodiments only and is not intended to limit of the embodiments. As used herein, the singular forms are intended to include the plural forms as well, unless the context clearly indicates otherwise. It will be further understood that the terms “comprises”, “includes”, “including”, and/or “comprising,” when used in this specification, specify the presence of stated constituent elements, steps, operations, and/or components, but do not preclude the presence or addition of one or more other constituent elements, steps, operations, and/or components thereof. The term “and/or” may include a combination of a plurality of items or any one of a plurality of items.

Hereinafter, a semiconductor device and a method for manufacturing the same according to embodiments of the present disclosure will be described in detail with reference to the attached drawings.

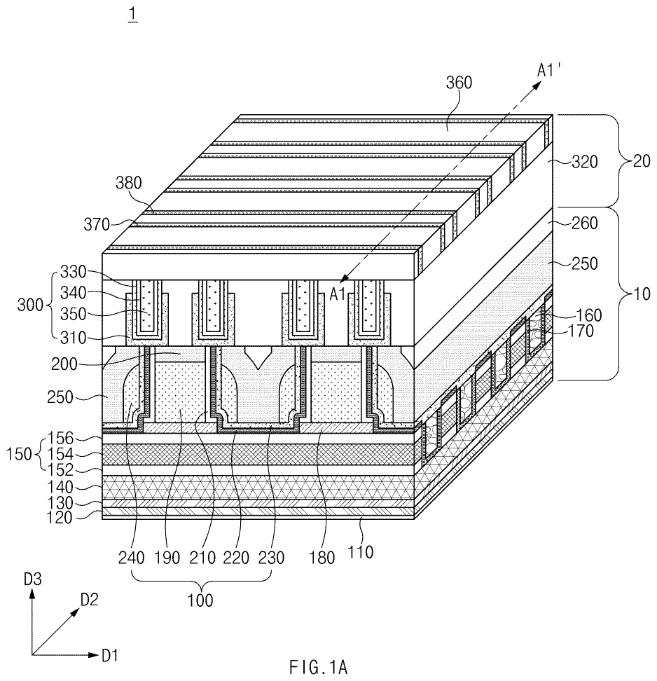

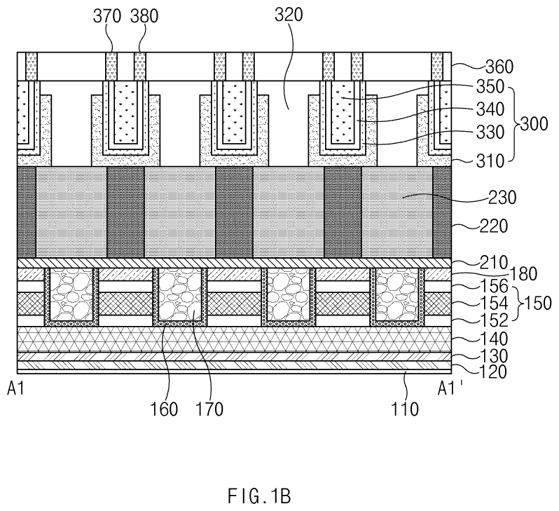

FIG. 1A is a cross-sectional view illustrating a portion of a semiconductor device 1 according to an embodiment of the present disclosure.

FIG. 1B is a cross-sectional view illustrating a configuration of the semiconductor device 1 taken along the first cutting line (A1-A1′) of FIG. 1A.

A detailed structure of the semiconductor device 1 according to an embodiment of the present disclosure will hereinafter be described with reference to FIGS. 1A and 1B.

The semiconductor device 1 may include a write transistor region 10 and a storage transistor region 20. The storage transistor region 20 may be located in a third direction (D3) with respect to the write transistor region 10. The storage transistor region 20 may be disposed over the transistor region 10.

The write transistor region 10 may include a plurality of write transistors 100. The storage transistor region 20 may include a plurality of storage transistors 300.

The write transistor region 10 may include a substrate layer 110, a first stacked layer 120 formed over the substrate layer 110, a second stacked layer 130 formed over the first stacked layer 120, and a third stacked layer 140 formed over the second stacked layer 130.

The substrate layer 110 may include a silicon semiconductor material. For example, the substrate layer 110 may include silicon, monocrystalline silicon, polysilicon, amorphous silicon, silicon germanium, monocrystalline silicon germanium, polycrystalline silicon germanium, carbon-doped silicon, and the like. The substrate layer 110 may include a plurality of control circuits configured to control the operation of the semiconductor device 1, and a region in which the control circuits are provided will hereinafter be referred to as a peripheral circuit section.

The first stacked layer 120 disposed over the substrate layer 110 may include a metal silicide material such as cobalt silicide (CoSi). As the first stacked layer 120 includes a metal silicide material, the operational electrical resistance of the semiconductor device may be reduced. In addition, the first stacked layer 120 may serve as a protective layer for the substrate layer 110 helping prevent damage to the substrate layer 110 during the semiconductor manufacturing process.

The second stacked layer 130 is disposed over the first stacked layer 120 and may be a layer including silicon nitride. Since the second stacked layer 130 includes silicon nitride, damage to the substrate layer 110 may be prevented during a high-temperature semiconductor manufacturing process.

A third stacked layer 140 may be disposed over the second stacked layer 130. The third stacked layer 140 may be a layer including silicon oxide, and the like.

The second stacked layer 130 and the third stacked layer 140 electrically isolate the control circuits in the substrate layer 110 from the write bitline 150.

The write transistor region 10 may include a write bitline 150, a first write bitline isolation layer 160, a second write bitline isolation layer 170, and a third write bitline isolation layer 180 that are disposed on the third stacked layer 140.

The write bitline 150 may include a plurality of layers extending in a first direction (D1). For example, as illustrated in the embodiment of FIG. 1A, the write bitline 150 may include a first write bitline layer 152, a second write bitline layer 154 disposed on the first write bitline layer 152, and a third write bitline layer 156 disposed on the second write bit line layer 154. For example, the first write bitline layer 152 may include titanium nitride (TiN), the second write bitline layer 154 may include tungsten (W), and the third write bitline layer 156 may include titanium nitride (TiN).

The resistance of the write bitline 150 may be adjusted by controlling the materials of the plurality of layers included in the write bitline 150.

When the second write bitline layer 154 is exposed to oxygen, tungsten (W) may be oxidized, resulting in electrical short-circuit and defects. The first write bitline layer 152 and the third write bitline layer 156 included in the write bitline 150 may prevent the second write bitline layer 154 from being exposed to oxygen and being oxidized.

In addition, since titanium nitride (TiN) included in the first write bitline layer 152 has a higher adhesion to silicon oxide than tungsten (W), the first write bitline layer 152 is provided between the third stacked layer 140 and the second write bitline layer 154, thereby improving the interfacial stability of the write bitline 150.

The write bitline 150 may be formed by depositing a plurality of layers and then performing an etching process using a mask.

The write bitline 150 may be referred to as a first bitline.

A first write bitline isolation layer 160 and a second write bitline isolation layer 170 may be disposed between adjacent write bitlines 150. In an embodiment, the first write bitline isolation layer 160 may include silicon nitride, and the second write bitline isolation layer 170 may include silicon oxide.

The third write bitline isolation layer 180 may be arranged to overlap with at least a portion of the write bitline 150. The third write bitline isolation layer 180 may include silicon oxide (SiCO) containing carbon. The third write bitline isolation layer 180 may electrically isolate the back-gate 190 and the write bitline 150 from each other. The third write bitline isolation layer 180 may extend in the second direction (D2), and may commonly overlap with the plurality of write bitlines 150.

In addition, the write transistor region 10 may include a back-gate 190 formed over the third write bitline isolation layer 180, a first back-gate isolation layer 200 formed over the back-gate 190, a second back-gate isolation layer 210, a first active region 220, a first write wordline isolation layer 230, a write wordline 240, a second write wordline isolation layer 250, and a third write wordline isolation layer 260.

The write transistor 100 may include a back-gate 190, a second back-gate isolation layer 210, a first active region 220, a first write wordline isolation layer 230, and a write wordline 240.

The back-gate 190 may extend in the second direction (D2). The back-gate 190 may include a metal, a metal mixture, a metal alloy, titanium nitride, tungsten, polysilicon, or a combination thereof. In an embodiment, the back-gate 190 may include titanium nitride.

The back-gate 190 may be provided with a voltage different from the voltage provided to the write wordline 240 in order to block interference between adjacent write wordlines 240. For example, when an active voltage level is provided to the write wordline 240, a ground voltage may be provided to the back-gate 190.

The first back-gate isolation layer 200 may be formed on the back-gate 190. The back-gate 190 and the storage transistor region 20 may be electrically isolated from each other by the first back-gate isolation layer 200. In an embodiment, the first back-gate isolation layer 200 may include silicon nitride.

The second back-gate isolation layer 210 may extend along a side surface of the back-gate 190, and may be formed over the third write bitline isolation layer 180. In an embodiment, the second back-gate isolation layer 210 may include silicon oxide.

According to an embodiment, the second back-gate isolation layer 210 may include a high-permittivity (high-k) material such as, for example, hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃).

The first active region 220 may include a channel region and a source/drain region of the write transistor 100. The first active region 220 may be a region where a channel is formed during the operation of the write transistor 100.

The first active region 220 may include a semiconductor material or an oxide semiconductor material. In an embodiment, the first active region 220 may include an oxide semiconductor material such as, for example, indium gallium zinc oxide (IGZO).

According to an embodiment, the first active region 220 may include doped polysilicon, undoped polysilicon, amorphous silicon, indium zinc oxide (IZO), indium tin oxide (ITO), indium oxide (InO₃), etc.

The first active region 220 may include a horizontal portion extending in the first direction (D1) and a vertical portion extending in the third direction (D3).

The horizontal portion included in the first active region 220 may contact the write bitline 150. In addition, the vertical portion included in the first active region 220 may have one side in contact with the horizontal portion and the other side in contact with the storage transistor 300.

A first write wordline isolation layer 230 may be arranged along the top (horizontal portion) and side surfaces (vertical portion) of the first active region 220. The first write wordline isolation layer 230 may be disposed between the first active region 220 and the write wordline 240 and may electrically isolate the write wordline 240 from the first active region 220. In an embodiment, the first write wordline isolation layer 230 may include silicon oxide.

According to an embodiment, the first write wordline isolation layer 230 may include a high-permittivity (high-k) material such as hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃).

The write wordline 240 may extend in the second direction (D2). The write wordline 240 may include a metal, a metal mixture, a metal alloy, titanium nitride, tungsten, polysilicon, or a combination thereof, and may include titanium nitride as an example.

The write wordline 240 may operate as a gate of the write transistor 100. The write wordline 240 may be a gate electrode to which an active voltage level is provided during the operation of the write transistor 100.

For example, the write wordline 240 may be referred to as a first wordline.

The second write wordline isolation layer 250 may be formed over the write wordline 240, and may be disposed between adjacent write wordlines 240. The second write wordline isolation layer 250 may electrically isolate the adjacent write wordlines 240 from each other. In addition, the second write wordline isolation layer 250 may electrically isolate the write wordlines 240 from the storage transistor 300. In an embodiment, the second write wordline isolation layer 250 may include silicon nitride.

The third write wordline isolation layer 260 may be formed over the second write wordline isolation layer 250. In an embodiment, the third write wordline isolation layer 260 may include silicon oxide.

The storage transistor region 20 including the storage transistor 300 may be formed over or on the write transistor region 10.

The storage transistor region 20 may include a storage gate 310 formed to contact the other end of the vertical portion of the first active region 220, a storage gate isolation layer 320 disposed between adjacent storage gates 310, a storage gate insulation layer 330 formed to overlap with the storage gate 310, a second active region 340 formed to overlap with the storage gate insulation layer 330, and a second active region insulation layer 350 formed over the second active region 340.

In addition, the storage transistor region 20 may include a storage gate isolation layer 320, a storage gate insulation layer 330, a second active region 340, and an isolation insulation layer 360 formed over the second active region insulation layer 350, a read bitline 370, and a read wordline 380.

Each storage transistor 300 may include a storage gate 310, a storage gate insulation layer 330, a second active region 340, and a second active region insulation layer 350.

The storage gate 310 may include a trench region therein. The trench region may extend in the third direction from one surface of the storage gate 310 toward the other surface opposite to the one surface. For example, the other surface of the storage gate 310 may be a surface where the storage gate 310 contacts the vertical portion of the first active region 220. More specifically, the storage gate 310 may have a flat bottom surface extending parallel to and in contact with a portion of the top surface of the second write wordline isolation layer 250, a portion of the top surface of the first back-gate isolation layer 200, the top surface of the first active region 220, the top surface of the second back-gate isolation layer 210, and the top surface of the first write wordline isolation layer 230. The storage gate 310 may also have vertically extending sides up to a height that is less than the height of the storage gate isolation layer 320.

The plurality of storage gates 310 may be arranged in a matrix shape over the write transistor region 10. Each storage gate 310 may be disposed to contact the vertical portion of a corresponding one of the first active regions 220.

A storage gate insulation layer 330, a second active region 340, and a second active region insulation layer 350 may be disposed in the trench included in the storage gate 310.

According to an embodiment, the storage gate 310 may be formed in a cylindrical shape including a trench. According to an embodiment, the storage gate 310 may be formed in a pillar shape extending in the third direction, and may include a trench formed inside the pillar.

The storage gate 310 may include a metal, a metal mixture, a metal alloy, titanium nitride, tungsten, polysilicon, or a combination thereof, and may include titanium nitride as an example.

Since the storage gate 310 includes the trench, the storage gate 310 may have a shape that surrounds a sidewall of the second active region 340.

More specifically, the storage gate insulation layer 330 may be formed along the sidewall and the bottom surface formed inside the trench included in the storage gate 310, and the second active region 340 may be formed along the sidewall and the bottom surface of the storage gate insulation layer 330. Therefore, the storage gate 310 may have a shape that surrounds the sidewall and the bottom surface of the second active region 340. Therefore, the storage gate 310 may be said to have a Gate All Around (GAA) shape.

The storage gate isolation layer 320 may be disposed between adjacent storage gates 310. The storage gate isolation layer 320 may include, for example, silicon oxide.

Since the storage gate isolation layer 320 is disposed between adjacent storage gates 310, the adjacent storage gates 310 may be electrically isolated from each other.

The storage gate insulation layer 330 may be formed to overlap with the storage gate 310 and may be disposed in a trench included in the storage gate 310. According to an embodiment, the storage gate insulation layer 330 may be arranged to overlap with the sidewall and the bottom surface of the trench.

The storage gate insulation layer 330 may include silicon oxide. The storage gate insulation layer 330 may be arranged between the storage gate 310 and the second active region 340, and may electrically isolate the storage gate 310 and the second active region 340 from each other.

The second active region 340 may be arranged to overlap with the storage gate insulation layer 330. More specifically, the second active region 340 may be arranged to overlap with the storage gate insulation layer 330 arranged along the sidewall and the bottom surface of the trench.

The second active region 340 may include a semiconductor material or an oxide semiconductor material. In an embodiment, the second active region 340 may include an oxide semiconductor material, such as, for example, indium gallium zinc oxide (IGZO).

According to an embodiment, the second active region 340 may include doped polysilicon, undoped polysilicon, amorphous silicon, indium zinc oxide (IZO), indium tin oxide (ITO), indium oxide (InO₃), and the like.

The second active region insulation layer 350 may be formed to fill at least a portion of the trench included in the storage gate 310. The second active region insulation layer 350 may include silicon oxide.

In addition, the storage transistor region 20 may include an isolation insulation layer 360, a read bitline 370 and a read wordline 380. The isolation insulation layer 360, the read bitline 370 and the read wordline 380 may be formed over the storage gate isolation layer 320, a storage gate insulation layer 330, a second active region 340 and the second active region insulation layer 350.

The isolation insulation layer 360 may include, for example, silicon nitride, and may be disposed between the read bitline 370 and the read wordline 380. The isolation insulation layer 360 may electrically isolate the read bitline 370 and the read wordline 380 from each other.

According to an embodiment, at least a portion of the silicon nitride layer serving as the isolation insulation layer 360 may be removed, and the read bitline 370 and the read wordline 380 may be formed in a region from which the silicon nitride layer is partially removed.

The read bitline 370 and the read wordline 380 may include a metal, a metal mixture, a metal alloy, titanium nitride, tungsten, polysilicon, or a combination thereof. For example, the read bitline 370 may include copper (Cu).

The read bitline 370 and the read wordline 380 may be arranged to contact the second active region 340. The read bitline 370 and the read wordline 380 may have a shape that extends in the first direction (D1).

The read bitline 370 and the read wordlines 380 adjacent to each other may commonly contact the plurality of second active regions 340 arranged parallel to each other in the first direction (D1).

For example, the read bitline 370 and the read wordline 380 may be referred to as the second bitline and the second wordline, respectively.

The plurality of second active regions 340 arranged parallel to each other in the first direction (D1) may be included in the plurality of storage transistors adjacent to each other in a column direction on the memory cell array, respectively. Accordingly, the semiconductor device according to the present disclosure may output a sum of signals output from a plurality of memory cells arranged parallel to each other in the column direction.

For example, each of the storage transistors 300 according to an embodiment of the present disclosure may store arbitrary cell data. Cell data stored in each storage transistor 300 may vary depending on a voltage provided to the write bitline 150 and the write wordline 240. In addition, arbitrary cell data may be stored in each memory cell by adjusting the voltage provided to each of the write bitline 150 and the write wordline 240,

As the read bitline 370 and the read wordline 380 adjacent to each other are included in different storage transistors 300 and are commonly connected to the plurality of second active regions 340 arranged parallel to each other in the first direction (D1), a current value corresponding to data of all cells stored in all storage transistors 300 sharing the read wordline 380 may be provided to one read bitline 370. Hence, this configuration may enable collective data readout from multiple storage transistors through a single read bitline, thereby enhancing read efficiency.

The cell data stored in each of the plurality of storage transistors 300 arranged in the first direction (D1) may correspond to a weight for a multiply-accumulate (MAC) operation. For example, each cell within the storage transistors 300—arranged along the first direction (D1)—may hold data representing a weight used in a multiply-accumulate (MAC) operation, which is a fundamental building block in neural networks and digital signal processing. This arrangement may enable storing weight values directly in memory cells, facilitating efficient hardware-based MAC computations.

As the active voltage level is provided to the read wordline 380, a current corresponding to cell data (e.g., a weight) stored in each of the plurality of storage transistors 300 sharing the read wordline 380 is provided to the read bitline 370 commonly contacting the plurality of storage transistors 300, and the read bitline 370 may output a current value corresponding to the sum of the cell data.

Accordingly, the semiconductor device according to an embodiment of the present disclosure may include a memory cell array that performs a multiply-accumulate (MAC) operation.

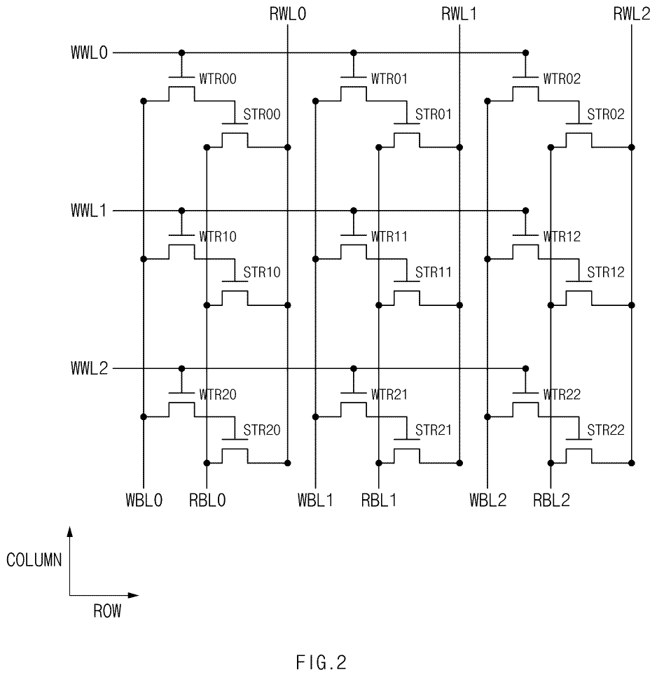

FIG. 2 is a circuit diagram illustrating a memory cell array of the semiconductor device according to an embodiment of the present disclosure.

The circuit diagram of FIG. 2 illustrates first to third write wordlines (WWL0, WWL1, WWL2) and first to third write bitlines (WBL0, WBL1, WBL2).

In addition, FIG. 2, shows nine distinct write transistors, each configured such that the write wordline interfaces with the gate region and the write bitline connects to either the source or drain region. Specifically, FIG. 2 shows first to ninth write transistors (WTR00, WTR01, WTR02, WTR10, WTR11, WTR12, WTR20, WTR21, WTR22), each of which is configured such that the write wordline contacts the gate region, while the write bitline connects to either the source or drain region.

The other one of the source/drain regions of the first to ninth write transistors (WTR00, WTR01, WTR02, WTR10, WTR11, WTR12, WTR20, WTR21, WTR22) may be formed to contact the gate of any one of the first to ninth storage transistors (STR00, STR01, STR02, STR10, STR11, STR12, STR20, STR21, STR22).

Any one of the source/drain regions of the first to ninth storage transistors (STR00, STR01, STR02, STR10, STR11, STR12, STR20, STR21, STR22) may be formed to contact any one of the first to third read bitlines (RBL0, RBL1, RBL2).

In addition, the other one of the source/drain regions of the first to ninth storage transistors (STR00, STR01, STR02, STR10, STR11, STR12, STR20, STR21, STR22) may be formed to contact the first to third read wordlines (RWL0, RWL1, RWL2).

The write transistors according to an embodiment of the present disclosure may share the write wordline extending in the row direction. For example, the first write wordline (WWL0) may be in common contact with the gates of the first write transistor (WTR00), the second write transistor (WTR01), and the third write transistor (WTR02) adjacent to each other in the row direction.

In addition, the write transistors according to an embodiment of the present disclosure may share the write bitline extending in the column direction. For example, the first write bitline (WBL0) may be in common contact with the source/drain regions of the first write transistor (WTR00), the fourth write transistor (WTR10), and the seventh write transistor (WTR20) adjacent to each other in the column direction.

The storage transistors according to an embodiment of the present disclosure may share the read bitline and the read wordline extending in the column direction. For example, the first read bitline (RBL0) may be in common contact with the source/drain regions of the first storage transistor (STR00), the fourth storage transistor (STR10), and the seventh storage transistor (STR20) adjacent to each other in the column direction. In addition, the first read wordline (RWL0) may be in common contact with the remaining source/drain regions of the first storage transistor (STR00), the fourth storage transistor (STR10), and the seventh storage transistor (STR20) that are adjacent to each other in the column direction.

When the active voltage level is provided to an arbitrary write wordline and an arbitrary write bitline, cell data may be provided to the gate of the storage transistor through the write transistor.

The cell data provided to the storage transistor may be, for example, a weight for the multiply-accumulate (MAC) operation.

According to an embodiment, arbitrary storage transistors included in the memory cell array share the read wordline extending in the column direction, so that the read wordline signal may be commonly provided to the plurality of storage transistors arranged in the column direction.

For example, a read wordline signal having an active voltage level may be provided through the first read wordline (RWL0) that commonly contacts the first storage transistor (STR00), the fourth storage transistor (STR10), and the seventh storage transistor (STR20) that are adjacent to each other in the column direction.

When the read wordline signal having an active voltage level is provided to the storage transistor, a current corresponding to cell data stored in each of a plurality of storage transistors sharing the read wordline is provided to a read bitline commonly contacting the plurality of storage transistors, and the read bitline may output a current value corresponding to the sum of the cell data.

For example, a current corresponding to the sum of cell data stored in each of the first storage transistor (STR00), the fourth storage transistor (STR10), and the seventh storage transistor (STR20) may be output through the first read bitline (RBL0) that commonly contacts the first storage transistor (STR00), the fourth storage transistor (STR10), and the seventh storage transistor (STR20) that are adjacent to each other in the column direction.

According to an embodiment, for the memory cell array of the semiconductor device, cell data stored in the plurality of storage transistors (e.g., the first storage transistor STR00, the fourth storage transistor STR10, and the seventh storage transistor STR20) arranged in the column direction may correspond to a weight matrix for the multiply-accumulate (MAC) operation.

In the memory cell array of FIG. 2, when an active voltage level is provided to the first read wordline (RWL0), a current corresponding to a value obtained by performing the MAC (multiply-accumulate) operation between the active voltage level provided to the first read wordline (RWL0) and cell data stored in the first storage transistor (STR00), the fourth storage transistor (STR10), and the seventh storage transistor (STR20) may be output through the first read bitline (RBL0).

Therefore, the semiconductor device according to an embodiment of the present disclosure may provide a memory cell array that performs the MAC (multiply-accumulate) operation.

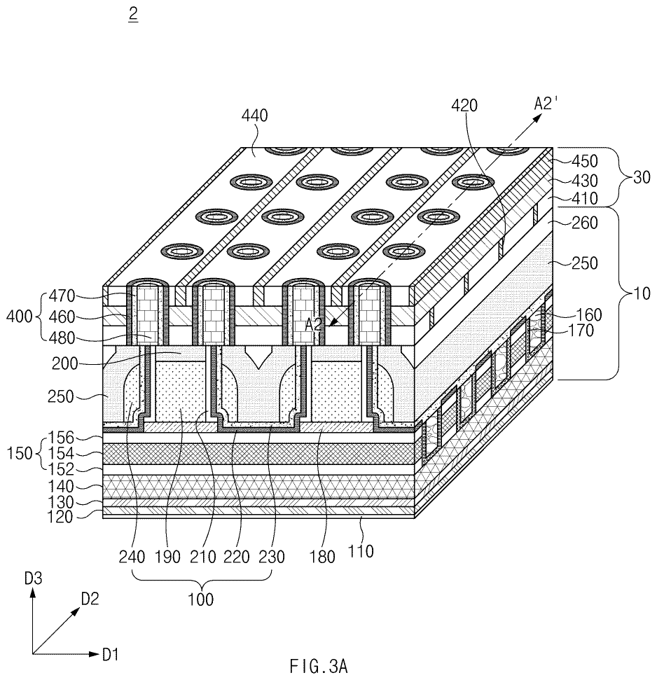

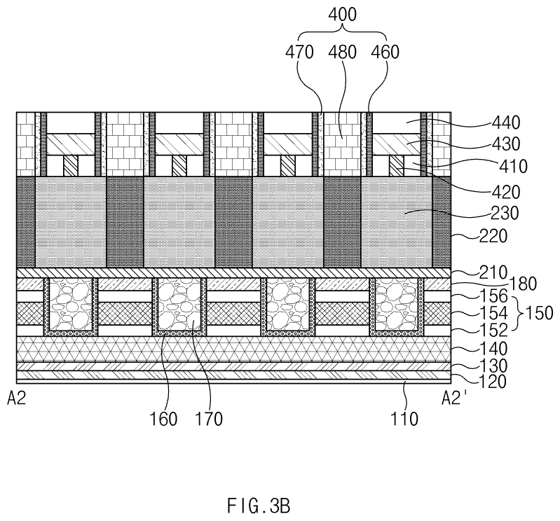

FIG. 3A is a diagram illustrating a portion of a semiconductor device according to another embodiment of the present disclosure.

FIG. 3B is a cross-sectional view illustrating a configuration of the semiconductor device taken along the second cutting line (A2-A2′) of FIG. 3A according to another embodiment of the present disclosure.

The semiconductor device 2 may include a write transistor region 10 and a storage transistor region 30 arranged in the third direction (D3).

The write transistor region 10 may include a plurality of write transistors 100, and the storage transistor region 30 may include a plurality of storage transistors 400.

The write transistor region 10 described with reference to FIGS. 3A and 3B is substantially the same as the write transistor region 10 described with reference to FIGS. 1A and 1B, and as such redundant description thereof will herein be omitted for brevity.

According to an embodiment, the storage transistor region 30 including the storage transistor 400 may be arranged over or on the write transistor region 10.

The storage transistor region 30 may include a read bitline 410, a read bitline isolation layer 420, an isolation insulation layer 430, a read wordline 440, a read wordline isolation layer 450, a second active region 460, a storage gate insulation layer 470, and a storage gate 480.

Each storage transistor 400 may include a storage gate 480, a storage gate insulation layer 470, and a second active region 460.

The plurality of storage gates 480 may be arranged in a matrix shape over the write transistor region 10. Each storage gate 480 may be arranged to contact a vertical portion of the first active region 220.

According to an embodiment, the storage gate 480 may have a cylindrical shape extending in the third direction (D3). According to an embodiment, the storage gate 480 may have a pillar shape extending in the third direction (D3).

The storage gate 480 may include a metal, a metal mixture, a metal alloy, titanium nitride, tungsten, polysilicon, or a combination thereof, and may include titanium nitride as an example.

The storage gate insulation layer 470 may be formed to surround the sidewall of the storage gate 480.

The storage gate insulation layer 470 may include silicon oxide. The storage gate insulation layer 470 may be disposed between the storage gate 480 and the second active region 460, and may electrically isolate the storage gate 480 and the second active region 460 from each other.

The second active region 460 may be arranged to surround the sidewall of the storage gate insulation layer 470. Therefore, the second active region 460 may be said to have a Channel-All-Around (CAA) shape.

The second active region 460 may include a semiconductor material or an oxide semiconductor material. In an embodiment, the second active region 460 may include an oxide semiconductor material, such as, for example, IGZO (Indium Gallium Zinc Oxide).

According to an embodiment, the second active region 460 may include doped polysilicon, undoped polysilicon, amorphous silicon, indium zinc oxide (IZO), indium tin oxide (ITO), indium oxide (InO₃), etc.

In addition, the storage transistor region 30 may include a read bitline 410 formed to contact an upper portion of the write transistor region 10, a read bitline isolation layer 420 disposed between adjacent read bitlines 410, an isolation insulation layer 430 formed over the read bitline 410 and the read bitline isolation layer 420, a read wordline 440 formed over the isolation insulation layer 430, and a read wordline isolation layer 450 disposed between adjacent read wordlines 440.

The read bitline 410 may include a metal, a metal mixture, a metal alloy, titanium nitride, tungsten, polysilicon, or a combination thereof. In an embodiment, it may include copper (Cu).

The read bitline 410 may extend in the first direction (D1), and a read bitline isolation layer 420 may be disposed between adjacent read bitlines 410. The read bitline isolation layer 420 may include, for example, silicon nitride.

For example, the read bitline 410 may be referred to as a second bitline.

The isolation insulation layer 430 may include, for example, silicon nitride, and may be arranged between the read bitline 410 and the read wordline 440.

In addition, the isolation insulation layer 430 may be formed over the read bitline 410 and the read bitline isolation layer 420, and may electrically isolate the read bitline 410 and the read wordline 440 from each other. According to an embodiment, the isolation insulation layer 430 may include silicon nitride.

The read wordline 440 may extend in the second direction (D2), and the read wordline isolation layer 450 may be disposed between adjacent read wordlines 440. The read wordline isolation layer 450 may include, for example, silicon nitride.

The read wordline 440 may hereinafter be referred to also as a second wordline.

The read bitline 410 and the read wordline 440 may be arranged to contact a sidewall of the second active region 460. More specifically, each of the read bitline 410 and the read wordline 440 may be formed to surround at least a portion of the sidewall of the second active region 460.

The read bitline 410 may commonly contact a plurality of second active regions 460 arranged parallel to each other in the first direction (D1).

The read wordline 440 may be in common contact with a plurality of second active regions 460 arranged parallel to each other in the second direction (D2).

According to an embodiment, the storage gate 480 and the second active region 460 may be formed in a region where the read bitline 410 overlaps with the read wordline 440.

In addition, the storage gate 480 may be formed to overlap with the vertical portion of the first active region 220.

According to an embodiment, the memory cell may include the write transistor 100 and the storage transistor 400, so that the memory cell may perform the write operation and the read operation using the write transistor 100 and the storage transistor 400.

When a signal corresponding to an active voltage level is provided to the write wordline 240, the write transistor 100 may be turned on. When the write transistor 100 is turned on, a voltage fluctuation may occur in the storage gate 480 due to the voltage provided to the write bitline 150. At this time, the type of data (e.g., 0 or 1) stored in the storage gate 480 may be determined according to the voltage provided to the write bitline 150. The above-described operation may be referred to as a write operation.

When a signal other than the active voltage level is provided to the write wordline 240, the write transistor 100 may be turned off. When the write transistor 100 is turned off, the on/off operation of the storage transistor 400 may be determined based on the voltage fluctuation that occurs in the storage gate 480 during the write operation.

During the read operation, the active voltage level may be provided to the read wordline 440. Accordingly, when the storage transistor 400 is turned on, a signal corresponding to the active voltage level may be output through the read bitline 410, and when the storage transistor 400 is turned off, a signal corresponding to an inactive voltage level (also called a non-active voltage level or a deactivation voltage level) may be output through the read bitline 410. The operation of outputting the signal corresponding to the voltage fluctuation that occurs in the storage gate 480 during the write operation may be referred to as a read operation.

The semiconductor device according to the embodiment of the present disclosure may provide a memory cell array that performs a data write operation and a data read operation.

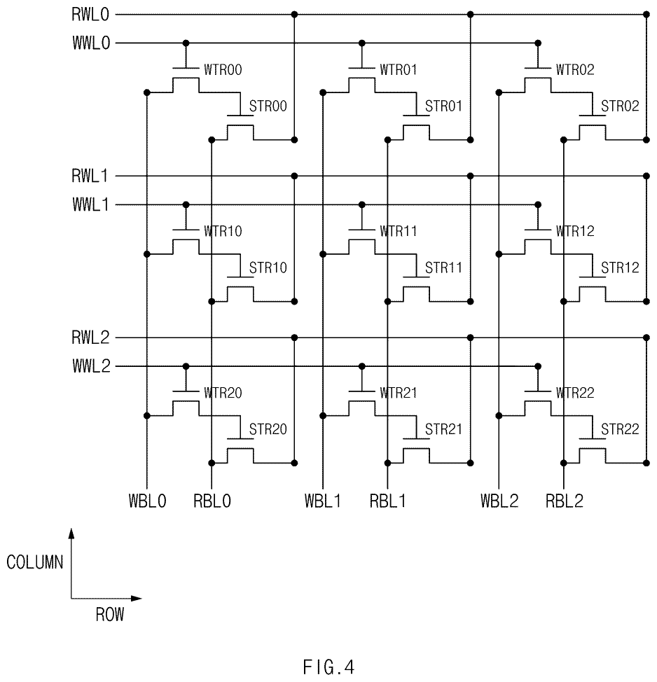

FIG. 4 is a circuit diagram illustrating a memory cell array of a semiconductor device according to another embodiment of the present disclosure.

As can be seen from the circuit diagram of FIG. 4, the first to third write wordlines (WWL0, WWL1, WWL2) and the first to third write bitlines (WBL0, WBL1, WBL2) are illustrated.

In addition, FIG. 4 illustrates the first to ninth write transistors (WTR00, WTR01, WTR02, WTR10, WTR11, WTR12, WTR20, WTR21, WTR22), each of which is configured such that the write wordline contacts a gate region and a write bitline contacts one of the source/drain regions.

The other one of the source/drain regions of the first to ninth write transistors (WTR00, WTR01, WTR02, WTR10, WTR11, WTR12, WTR20, WTR21, WTR22) may be formed to contact the gate of one of the first to ninth storage transistors (STR00, STR01, STR02, STR10, STR11, STR12, STR20, STR21, STR22).

One of the source/drain regions of the first to ninth storage transistors (STR00, STR01, STR02, STR10, STR11, STR12, STR20, STR21, STR22) may be formed to contact one of the first to third read bitlines (RBL0, RBL1, RBL2).

In addition, the other one of the source/drain regions of the first to ninth storage transistors (STR00, STR01, STR02, STR10, STR11, STR12, STR20, STR21, STR22) may be formed to contact one of the first to third read wordlines (RWL0, RWL1, RWL2).

The write transistors according to an embodiment of the present disclosure may share the write wordline extending in the row direction. For example, the first write wordline (WWL0) may be in common contact with the gates of the first write transistor (WTR00), the second write transistor (WTR01), and the third write transistor (WTR02) that are adjacent to each other in the row direction.

In addition, the write transistors according to an embodiment of the present disclosure may share the write bitline extending in the column direction. For example, the first write bitline (WBL0) may be in common contact with the source/drain regions of the first write transistor (WTR00), the fourth write transistor (WTR10), and the seventh write transistor (WTR20) that are adjacent to each other in the column direction.

The storage transistors according to an embodiment of the present disclosure may share the read bitline extending in the column direction. For example, the first read bitline (RBL0) may be in common contact with the source/drain regions of the first storage transistor (STR00), the fourth storage transistor (STR10), and the seventh storage transistor (STR20) that are adjacent to each other in the column direction.

The storage transistors according to an embodiment of the present disclosure may share the read wordline extending in the row direction. For example, the first read wordline (RWL0) may be in common contact with the source/drain regions of the first storage transistor (STR00), the second storage transistor (STR01), and the third storage transistor (STR03) that are adjacent to each other in the row direction.

When the active voltage level is provided to an arbitrary write wordline and an arbitrary write bitline, cell data may be provided to the gate of the storage transistor through the write transistor.

For example, when a signal corresponding to the active voltage level is provided to the first write wordline (WWL0), the first write transistor (WTR00), the second write transistor (WTR01), and the third write transistor (WTR02) may be turned on.

When a signal corresponding to the active voltage level is provided to an arbitrary write wordline, a voltage fluctuation may occur in a storage gate included in a storage transistor due to the voltage provided to the arbitrary write bitline.

For example, when a signal corresponding to the active voltage level is provided to the first write wordline (WWL0), a voltage fluctuation may occur in a storage gate included in the first storage transistor (STR00) due to the voltage provided to the first write bitline (WBL0).

At this time, the type of data (e.g., 0 or 1) stored in the storage gate may be determined according to the voltage provided to the write bitline. The above-described operation may be referred to as a write operation.

When an inactive voltage level (also called a non-active voltage level or a deactivation voltage level) is provided to the write wordline, the write transistor may be turned off. When the write transistor is turned off, the on/off operation of the storage transistor may be determined based on the voltage fluctuation generated in the write operation.

An operation of outputting a signal corresponding to the voltage fluctuation that occurs in the storage gate during the write operation may be referred to as a read operation.

For example, during the write operation, when a signal corresponding to the active voltage level is provided to the first write wordline (WWL0) and the first write bitline (WBL0), a voltage fluctuation may occur in the storage gate included in the first storage transistor (STR00). Although an inactive voltage level (also called a non-active voltage level or a deactivation voltage level) is provided to the first write wordline (WWL0), the first storage transistor (STR00) may maintain a turned-on state.

Therefore, during the read operation, when the active voltage level is provided to the first read wordline (RWL0), a signal corresponding to the active voltage level may be output to the first read bitline (RBL0) by the first storage transistor (STR00) that remains turned on.

When data is not stored in the gate of the first storage transistor (STR00) during the write operation, the first storage transistor (STR00) may be kept in a turned-off state during the read operation, so that a signal corresponding to the inactive voltage level (i.e., a non-active voltage level or a deactivation voltage level) may be output through the first read bitline (RBL0).

The semiconductor device according to an embodiment of the present disclosure may store data in an arbitrary memory cell included in a memory cell array, or may selectively output the stored data. The semiconductor device according to an embodiment of the present disclosure may read and/or write data.

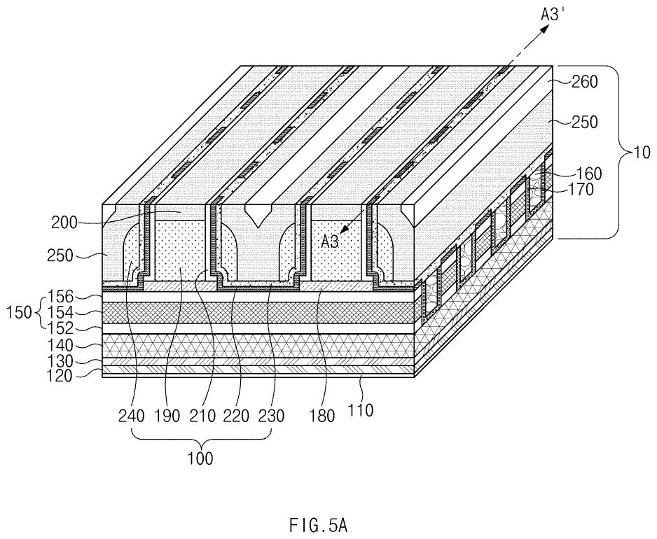

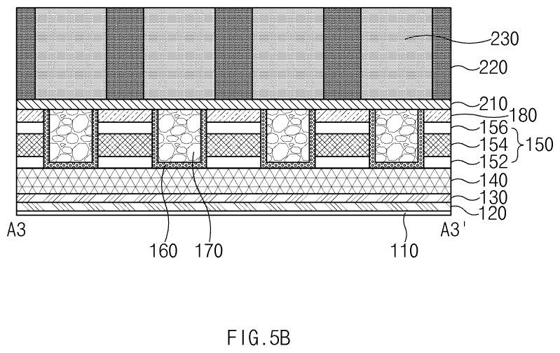

FIGS. 5A to 15B are diagrams illustrating a method for manufacturing the semiconductor device according to an embodiment of the present disclosure.

In FIGS. 5A and 5B, the shape of a write transistor region 10 is specifically illustrated.

FIG. 5A is a perspective view of the write transistor region 10. Referring to FIG. 5A, the front of the perspective view may be a cross-sectional view of the write transistor region 10 taken along the cutting line that passes through the center of the write bitline 150 and extends in the first direction (D1).

In addition, the side surface of the perspective view may be a cross-sectional view of the write transistor region 10 taken along the cutting line extending in the second direction (D2) of the write transistor region 10.

FIG. 5B is a cross-sectional view illustrating a configuration of the semiconductor device taken along the third cutting line (A3-A3′) shown in FIG. 5A based on an embodiment of the present disclosure.

The third cutting line (A3-A3′) may be the cutting line that passes through the center of the vertical portion included in the first active region 220 and extends in the second direction (D2).

The structure of the write transistor region 10 has already been described in detail with reference to FIGS. 1A and 1B, and as such redundant description thereof will herein be omitted for brevity.

Referring to FIGS. 5A and 5B, the vertical portions respectively included in the plurality of first active regions 220 may be arranged spaced apart from each other by a preset distance with respect to the second direction (D2). In addition, the first active region 220 may include, for example, two vertical portions and one horizontal portion.

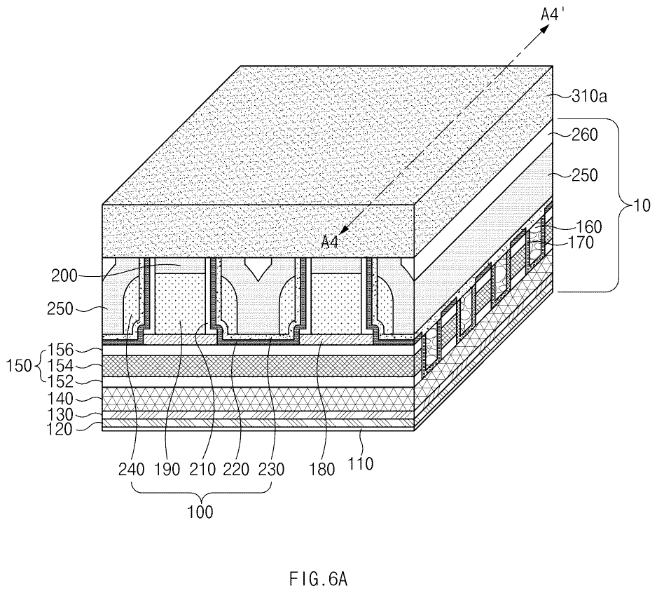

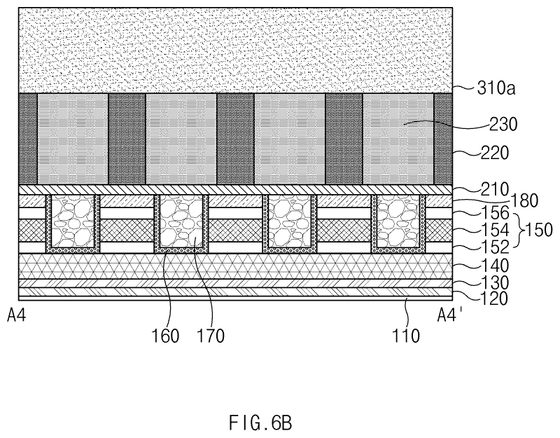

FIGS. 6A and 6B illustrate a process of forming a conductive material layer 310a over the write transistor region 10.

FIG. 6A is a perspective view illustrating a semiconductor device in which the conductive material layer 310a is formed over the write transistor region 10.

FIG. 6B is a cross-sectional view illustrating a configuration of the semiconductor device taken along the fourth cutting line (A4-A4′) of FIG. 6A based on an embodiment of the present disclosure.

According to an embodiment, the conductive material layer 310a may include a metal, a metal mixture, a metal alloy, titanium nitride, tungsten, polysilicon, or a combination thereof, and may include titanium nitride as an example.

The conductive material layer 310a may be formed by depositing a conductive material on the write transistor region 10.

The conductive material layer 310a may be arranged such that at least a portion of the conductive material layer 310a overlaps with the vertical portion of the first active region 220.

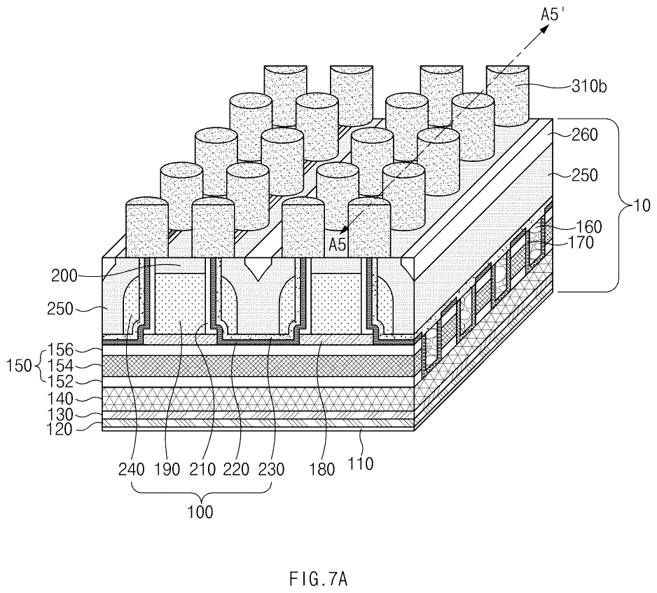

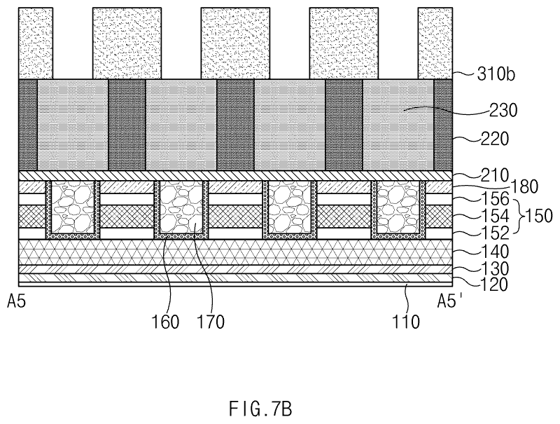

FIGS. 7A and 7B illustrate a process for etching a portion of the conductive material layer 310a and forming pre-storage gates 310b.

FIG. 7A is a perspective view illustrating a configuration of the semiconductor device in which pre-storage gates 310b are formed over the write transistor region 10.

FIG. 7B is a cross-sectional view illustrating a configuration of the semiconductor device taken along the fifth cutting line (A5-A5′) of FIG. 7A based on an embodiment of the present disclosure.

The pre-storage gates 310b may be formed by selectively etching a region of the conductive material layer 310a that does not overlap with the vertical portion of the first active region 220.

The pre-storage gates 310b may overlap with the vertical portions of the first active region 220.

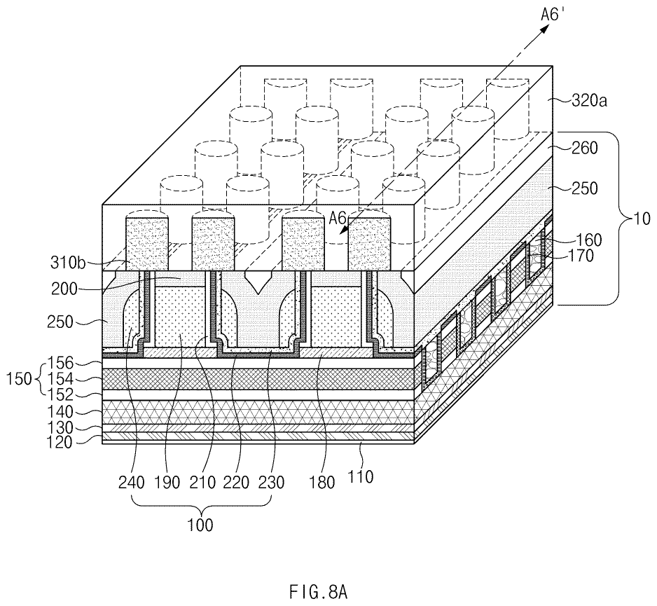

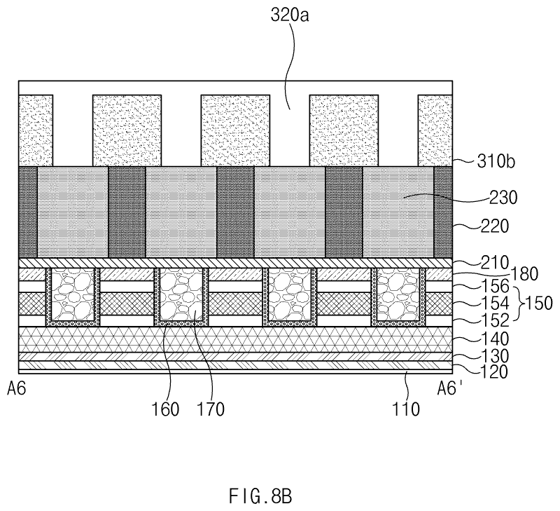

FIGS. 8A and 8B illustrate a process for forming a pre-storage gate isolation layer 320a over the pre-storage gates 310b.

FIG. 8A is a perspective view illustrating the pre-storage gate isolation layer 320a formed over the pre-storage gates 310b.

FIG. 8B is a cross-sectional view illustrating a configuration of the semiconductor device taken along the sixth cutting line (A6-A6′) of FIG. 8A based on an embodiment of the present disclosure.

For example, the pre-storage gate isolation layer 320a may include silicon oxide.

The pre-storage gate isolation layer 320a may be deposited between adjacent pre-storage gates 310b to electrically isolate the pre-storage gates 310b from each other.

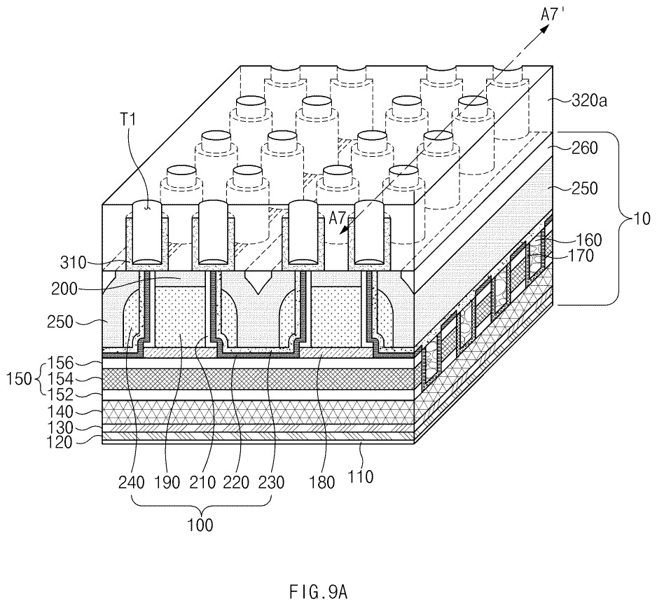

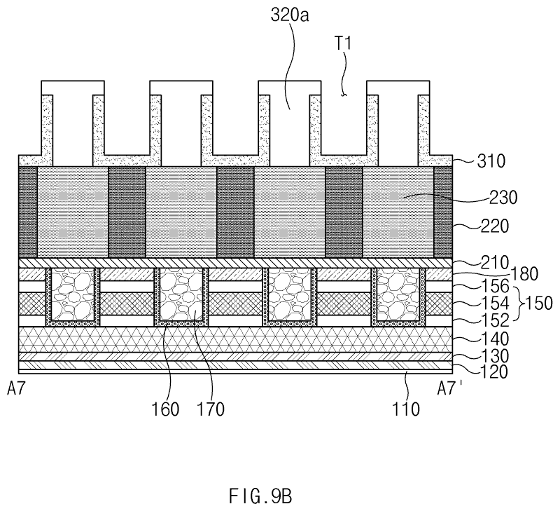

FIGS. 9A and 9B illustrate a process for etching at least a portion of each of the pre-storage gates 310b to form storage gates 310 and trench regions (T1).

FIG. 9A is a perspective view illustrating at least a portion of the pre-storage gate 310b etched.

FIG. 9B is a cross-sectional view illustrating a configuration of the semiconductor device taken along the seventh cutting line (A7-A7′) of FIG. 9A based on an embodiment of the present disclosure.

The trench regions (T1) may be formed by selectively etching the pre-storage gate isolation layer 320a and a portion of each of the pre-storage gate 310b.

Each storage gate 310 may be formed by forming the trench region (T1) within each of the pre-storage gates 310b.

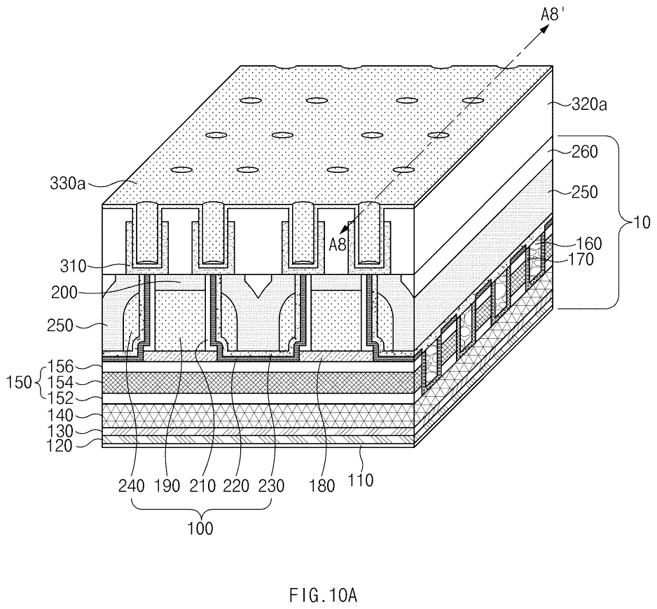

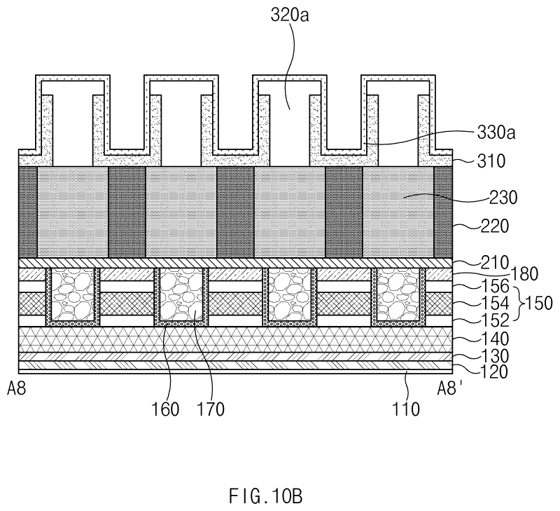

FIGS. 10A and 10B illustrate a process for forming a pre-storage gate insulation layer 330a within the trench region.

FIG. 10A is a perspective view illustrating a configuration of the semiconductor device in which a pre-storage gate insulation layer 330a is formed within the trench region (T1).

FIG. 10B is a cross-sectional view illustrating a configuration of the semiconductor device taken along the eighth cutting line (A8-A8′) of FIG. 10A.

The pre-storage gate insulation layer 330a may include, for example, silicon oxide. The pre-storage gate insulation layer 330a may be formed to contact the side and bottom surfaces of the trench regions (T1) formed within the storage gates 310.

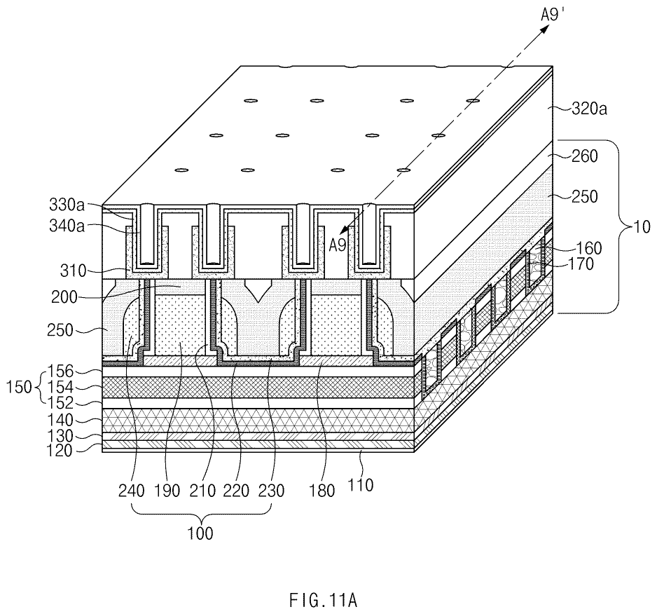

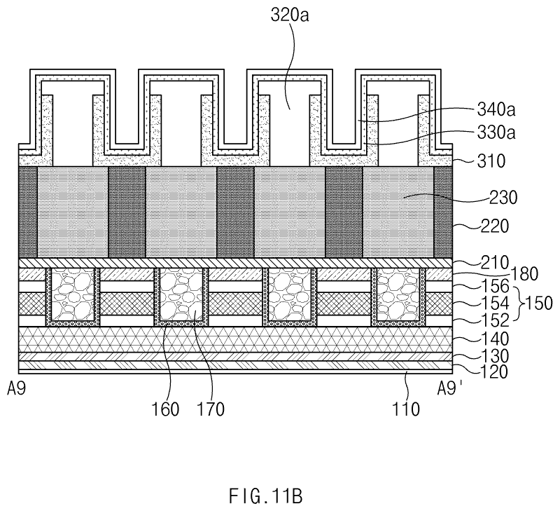

FIGS. 11A and 11B illustrate a process for forming a semiconductor material layer 340a over the pre-storage gate insulation layer 330a.

FIG. 11A is a perspective view illustrating a semiconductor material layer 340a formed over the pre-storage gate insulation layer 330a.

FIG. 11B is a cross-sectional view illustrating a configuration of the semiconductor device taken along the ninth cutting line (A9-A9′) of FIG. 11A.

The semiconductor material layer 340a may include, for example, a semiconductor material or an oxide semiconductor material. For example, the semiconductor material layer 340a may include an oxide semiconductor material, and the oxide semiconductor material may include IGZO (Indium Gallium Zinc Oxide).

According to another embodiment, the semiconductor material layer 340a may include doped polysilicon, undoped polysilicon, amorphous silicon, indium zinc oxide (IZO), indium tin oxide (ITO), indium oxide (InO₃), etc.

The semiconductor material layer 340a may contact the side and bottom surfaces of the pre-storage gate insulation layer 330a.

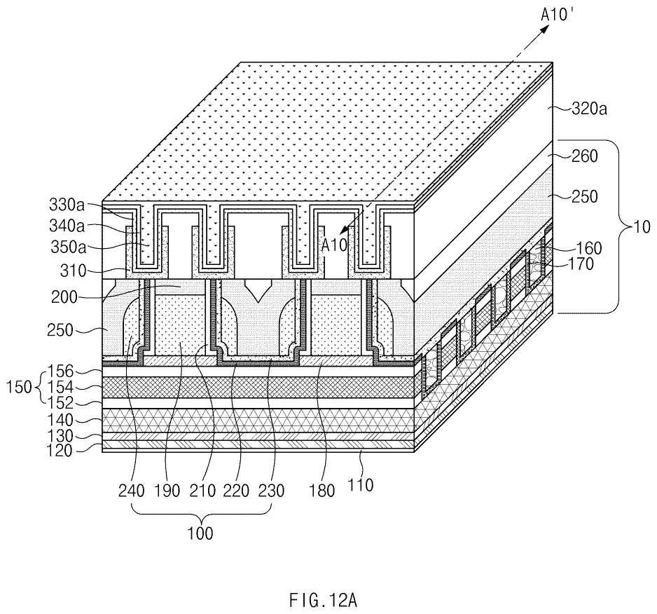

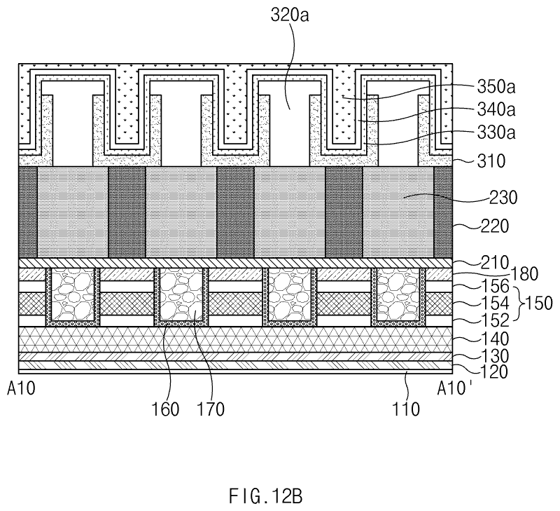

FIGS. 12A and 12B illustrate a process for forming the pre-active region insulation layer 350a over the semiconductor material layer 340a.

FIG. 12A is a perspective view illustrating a configuration of the semiconductor device in which the pre-active region insulation layer 350a is formed over the semiconductor material layer 340a.

FIG. 12B is a cross-sectional view illustrating a configuration of the semiconductor device taken along the tenth cutting line (A10-A10′) of FIG. 12A.

The pre-active region insulation layer 350a may include, for example, silicon oxide.

The pre-active region insulation layer 350a may be formed to fill at least a portion of the trench region disposed in each storage gate 310. In addition, at least a portion of the pre-active region insulation layer 350a may contact the side and bottom surfaces of the semiconductor material layer 340a.

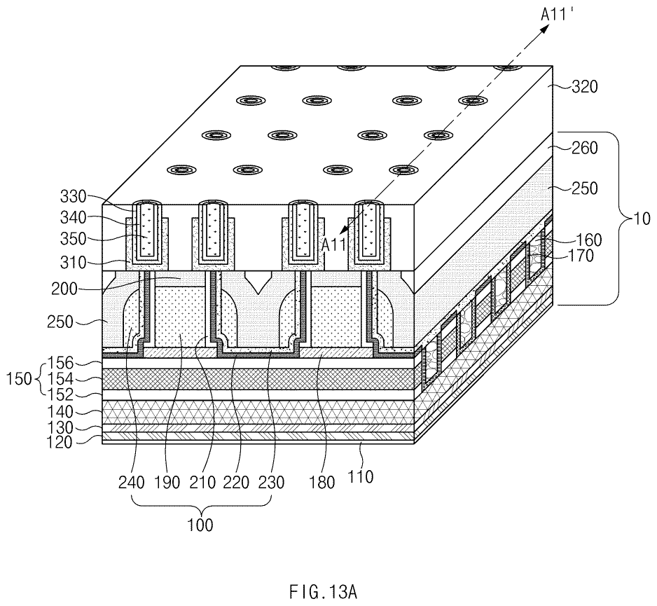

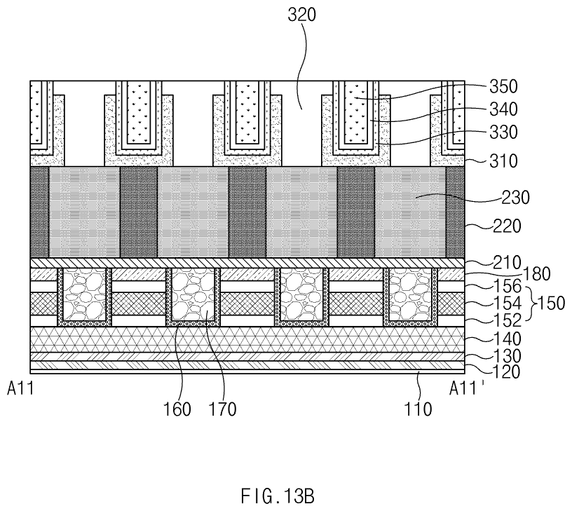

FIGS. 13A and 13B illustrate a process for etching at least a portion of the pre-active region insulation layer 350a, the semiconductor material layer 340a, the pre-storage gate insulation layer 330a, and the pre-storage gate isolation layer 320a.

FIG. 13A is a perspective view illustrating the semiconductor device in which at least a portion of the pre-active region insulation layer 350a, at least a portion of the semiconductor material layer 340a, at least a portion of the pre-storage gate insulation layer 330a, and at least a portion of the pre-storage gate isolation layer 320a are etched.

FIG. 13B is a cross-sectional view illustrating a configuration of the semiconductor device taken along the eleventh cutting line (A11-A11′) of FIG. 13A.

At least a portion of the pre-active region insulation layer 350a, at least a portion of the semiconductor material layer 340a, at least a portion of the pre-storage gate insulation layer 330a, and at least a portion of the pre-storage gate isolation layer 320a are etched, so that a second active region insulation layer 350, a second active region 340, a storage gate insulation layer 330, and a storage gate isolation layer 320 may be formed.

In addition, as the pre-active region insulation layer 350a is etched, at least a portion of the second active region 340 may be exposed.

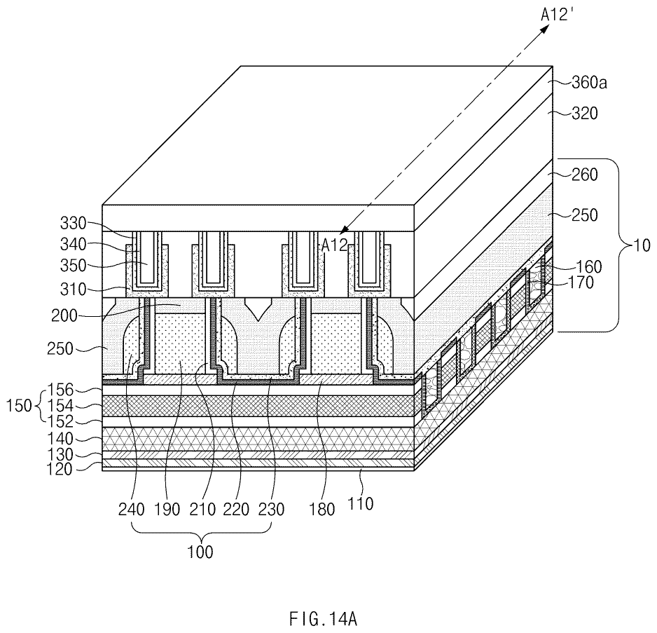

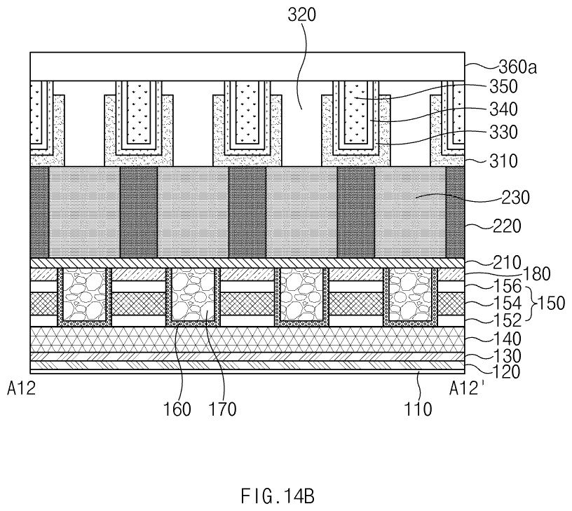

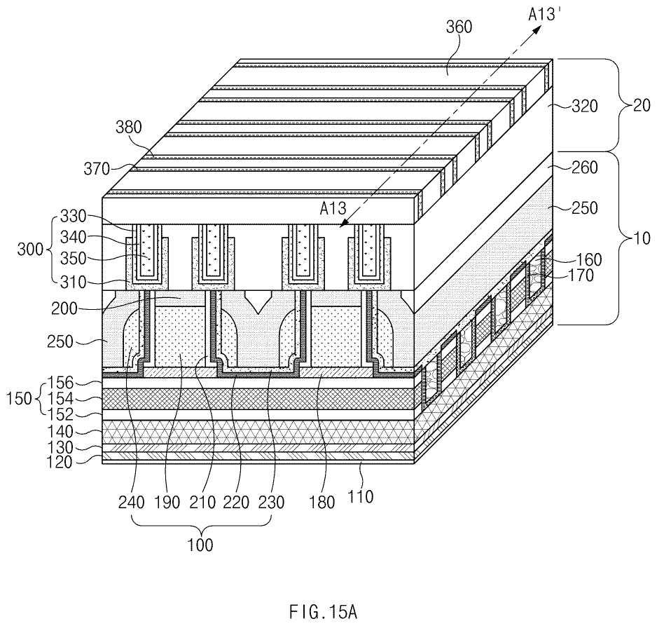

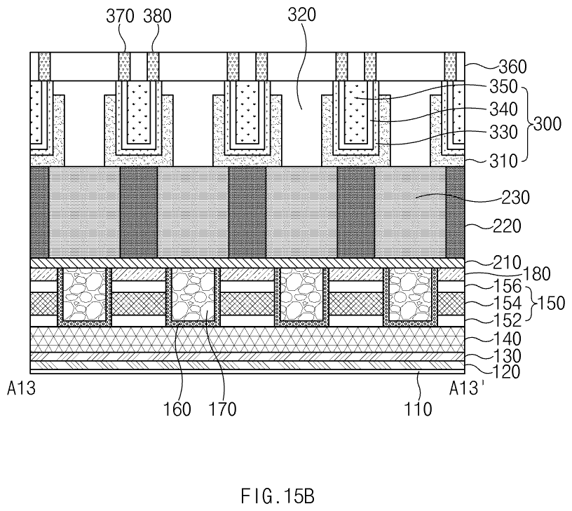

FIGS. 14A and 14B illustrate a process for forming a pre-isolation insulation layer 360a over the second active region insulation layer 350, the second active region 340, the storage gate insulation layer 330, and the storage gate isolation layer 320.

FIG. 14A is a perspective view illustrating a semiconductor device in which the pre-isolation insulation layer 360a is formed over the second active region insulation layer 350, the second active region 340, the storage gate insulation layer 330, and the storage gate isolation layer 320.

FIG. 14B is a cross-sectional view illustrating a configuration of the semiconductor device taken along the twelfth cutting line (A12-A12′) of FIG. 14A.

Referring to FIG. 14B, the pre-isolation insulation layer 360a may include, for example, silicon nitride.

FIGS. 15A and 15B illustrate a process for etching at least a portion of the pre-isolation insulation layer 360a and forming a read bitline 370 and a read wordline 380.

FIG. 15A is a perspective view illustrating a configuration of the semiconductor device in which the isolation insulation layer 360, the read bitline 370, and the read wordline 380 are formed.

FIG. 15B is a cross-sectional view illustrating a configuration of the semiconductor device taken along the thirteenth cutting line (A13-A13′) of FIG. 15A.

Referring to FIG. 15B, the read bitline 370 and the read wordline 380 may have a shape extending in the first direction (D1).

The read bitline 370 and the read wordline 380 may include a metal mixture, a metal alloy, titanium nitride, tungsten, polysilicon, or a combination thereof, and may include copper (Cu) as an example.

The read bitline 370 and the read wordline 380 may be formed by etching at least a portion of the pre-isolation insulation layer 360a formed to overlap with the second active region 340 and then depositing a conductive material.

The isolation insulation layer 360 may be disposed between the read bitline 370 and the read wordline 380.

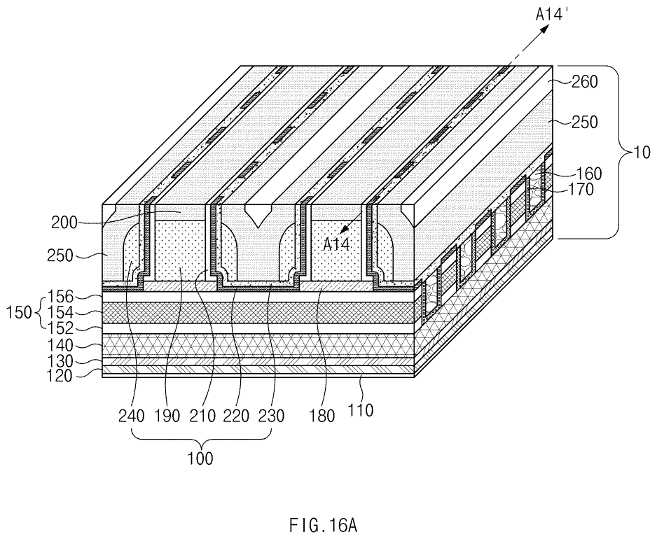

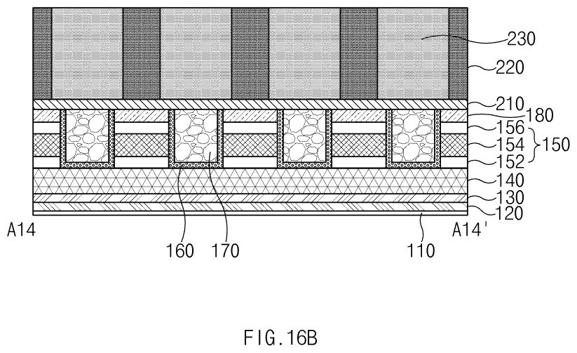

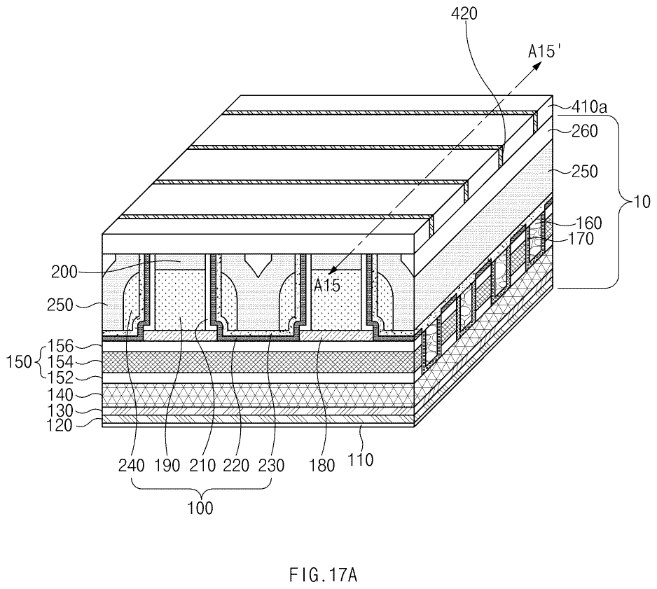

FIGS. 16A to 26B are diagrams illustrating a method for manufacturing the semiconductor device according to an embodiment of the present disclosure.

In FIGS. 16A and 16B, the shape of the write transistor region 10 is specifically illustrated.

FIG. 16A is a perspective view of the write transistor region 10.

FIG. 16B is a cross-sectional view illustrating a configuration of the semiconductor device taken along the fourteenth cutting line (A14-A14′) of FIG. 16A.

FIGS. 16A and 16B are identical in structure to FIGS. 5A and 5B, and as such redundant description thereof will herein be omitted for brevity.

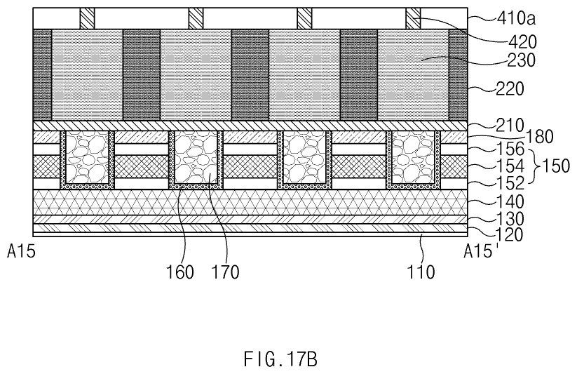

FIGS. 17A and 17B illustrate a process for forming a pre-read bitline 410a and a read bitline isolation layer 420 over the write transistor region 10.

FIG. 17A is a perspective view illustrating a configuration of the semiconductor device in which a pre-read bitline 410a and a read bitline isolation layer 420 are formed over the write transistor region 10.

FIG. 17B is a cross-sectional view illustrating a configuration of the semiconductor device taken along the fifteenth cutting line (A15-A15′) of FIG. 17A.

For example, the pre-read bitline 410a may include a metal, a metal mixture, a metal alloy, titanium nitride, tungsten, polysilicon, or a combination thereof. In an embodiment, it may include copper (Cu).

A pre-read bitline material layer is deposited over the write transistor region 10, and the deposited pre-read bitline material layer is isolated using the read bitline isolation layer 420, resulting in formation of the pre-read bitline 410a.

The read bitline isolation layer 420 may be disposed between adjacent pre-read bitlines 410a.

At least a portion of the deposited conductive material layer is etched in a shape extending in the first direction (D1), and silicon nitride or the like is deposited on the etched region, resulting in formation of the read bitline isolation layer 420.

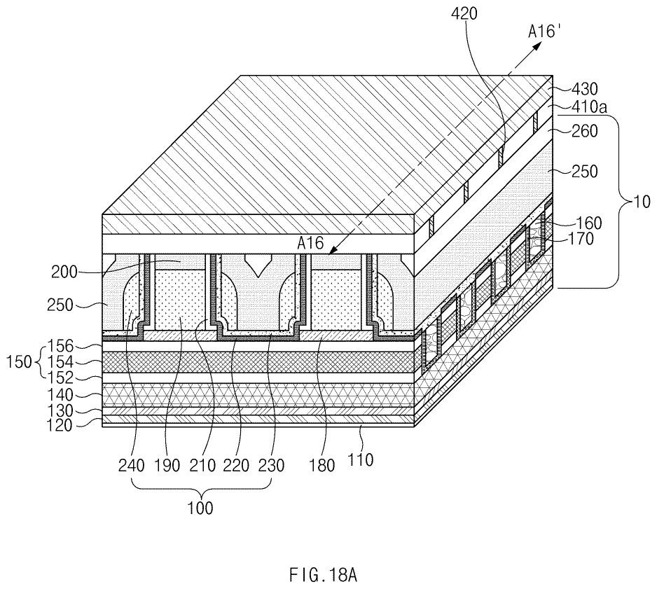

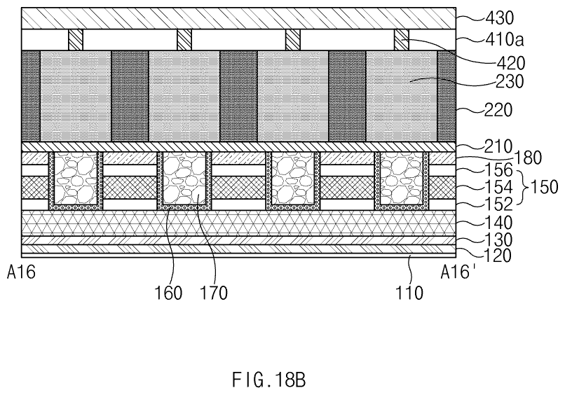

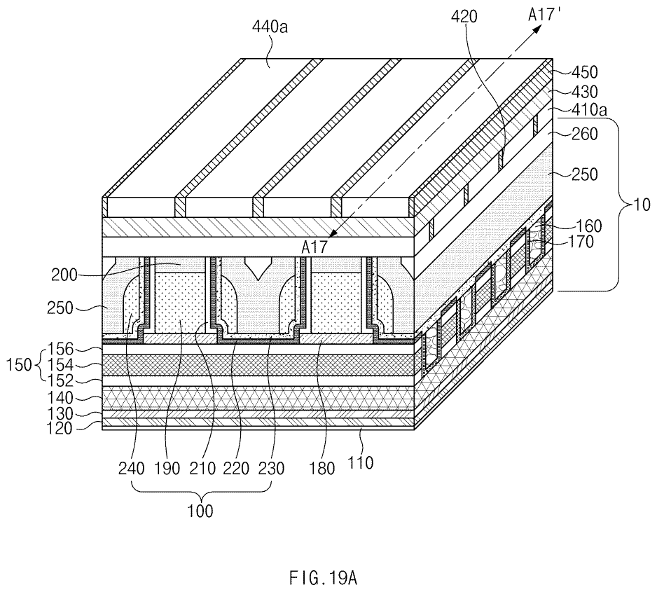

FIGS. 18A and 18B illustrate a process of forming an isolation insulation layer 430 over the pre-read bitline 410a and the read bitline isolation layer 420.

FIG. 18A is a perspective view illustrating a configuration of the semiconductor device in which the isolation insulation layer 430 is formed over the pre-read bitline 410a and the read bitline isolation layer 420.

FIG. 18B is a cross-sectional view illustrating a configuration of the semiconductor device taken along the sixteenth cutting line (A16-A16′) of FIG. 18A.

Referring to FIG. 18B, the isolation insulation layer 430 may include, for example, silicon nitride.

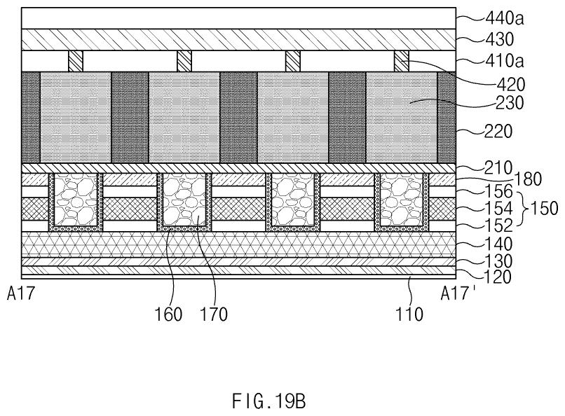

FIGS. 19A and 19B illustrate a process for forming a pre-read wordline 440a and a read wordline isolation layer 450 over the isolation insulation layer 430.

FIG. 19A is a perspective view illustrating a configuration of the semiconductor device in which the pre-read wordline 440a and the read wordline isolation layer 450 are formed over the isolation insulation layer 430.

FIG. 19B is a cross-sectional view illustrating a configuration of the semiconductor device taken along the seventeenth cutting line (A17-A17′) of FIG. 19A.

For example, the pre-read wordline 440a may include a metal, a metal mixture, a metal alloy, titanium nitride, tungsten, polysilicon, or a combination thereof. In an embodiment, it may include copper (Cu).

A pre-read wordline material layer is deposited on the isolation insulation layer 430, and the deposited pre-read wordline material layer is isolated using the read wordline isolation layer 450, resulting in formation of the pre-read wordline 440a.

The read wordline isolation layer 450 may be disposed between adjacent pre-read wordlines 440a.

At least a portion of the deposited conductive material layer is etched in a shape extending in the second direction (D2), and silicon nitride or the like is deposited on the etched region, resulting in formation of the read wordline isolation layer 450.

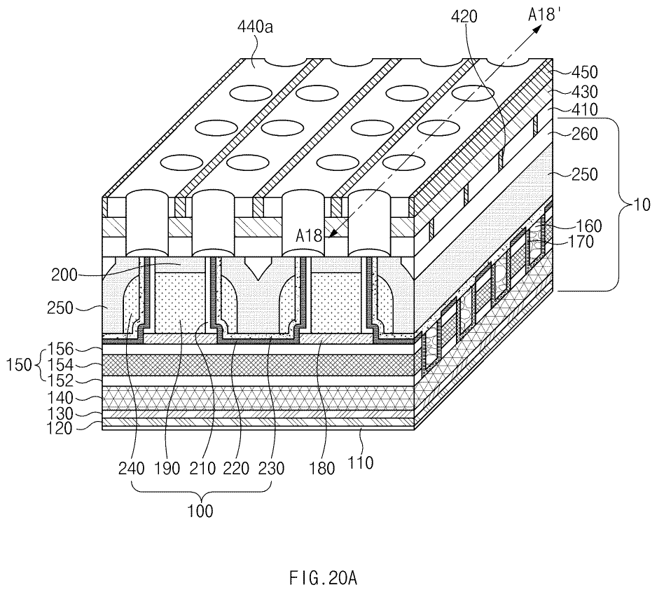

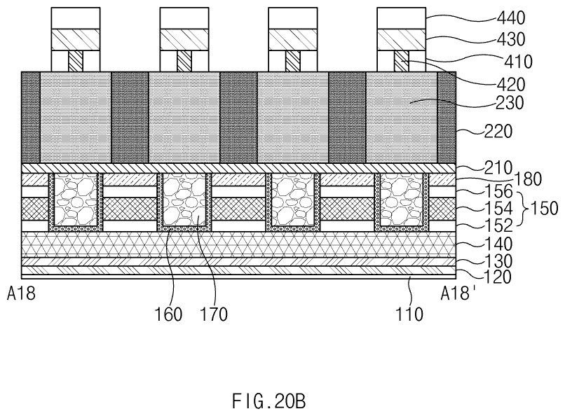

FIGS. 20A and 20B illustrate a process of etching at least a portion of the pre-read wordline 440a, the isolation insulation layer 430, and the pre-read bitline 410a.

FIG. 20A is a perspective view illustrating a configuration of the semiconductor device in which the pre-read wordline 440a, the isolation insulation layer 430, and the pre-read bitline 410a are etched.

FIG. 20B is a cross-sectional view illustrating a configuration of the semiconductor device taken along the eighteenth cutting line (A18-A18′) of FIG. 20A.

Referring to FIG. 20B, at least a portion of the pre-read wordline 440a and the pre-read bitline 410a that are formed to overlap with the vertical portion of the first active region 220 may be selectively etched, so that the read wordline 440 and the read bitline 410 may be formed.

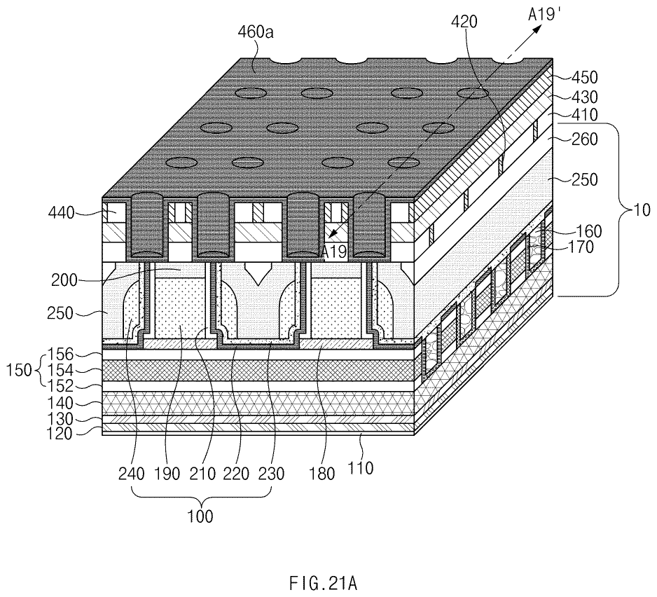

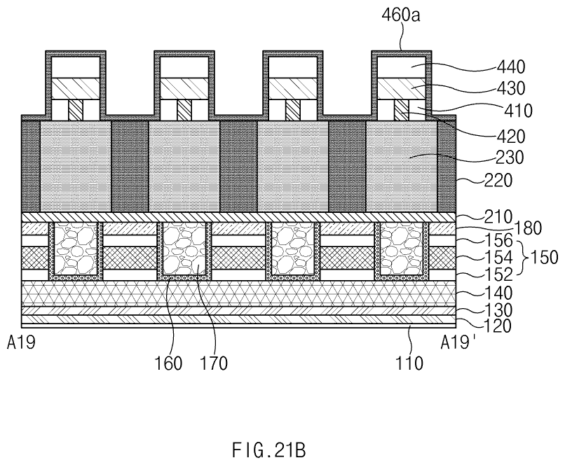

FIGS. 21A and 21B illustrate a process for forming a semiconductor material layer 460a that contacts the read wordline 440, the isolation insulation layer 430, and the read bitline 410.

FIG. 21A is a perspective view illustrating the semiconductor device in which the semiconductor material layer 460a that contacts the read wordline 440, the isolation insulation layer 430, and the read bitline 410 is formed.

FIG. 21B is a cross-sectional view illustrating a configuration of the semiconductor device taken along the nineteenth cutting line (A19-A19′) of FIG. 21A.

The semiconductor material layer 460a may include, for example, a semiconductor material or an oxide semiconductor material. For example, the oxide semiconductor material may include IGZO (Indium Gallium Zinc Oxide).

According to another embodiment, the semiconductor material layer 460a may include doped polysilicon, undoped polysilicon, amorphous silicon, indium zinc oxide (IZO), indium tin oxide (ITO), indium oxide (InO₃), etc.

The semiconductor material layer 460a may contact the etched side surfaces of the read wordline 440 and the read bitline 410. The semiconductor material layer 460a may also contact the isolation insulation layer 430 which is disposed between the read wordline 440 and the read bitline 410. The semiconductor material layer 460a may also be formed over the exposed top surfaces of the first active regions 220 and of the portions of the first write wordline isolation layer 230 that do not overlap with the read wordlines 440.

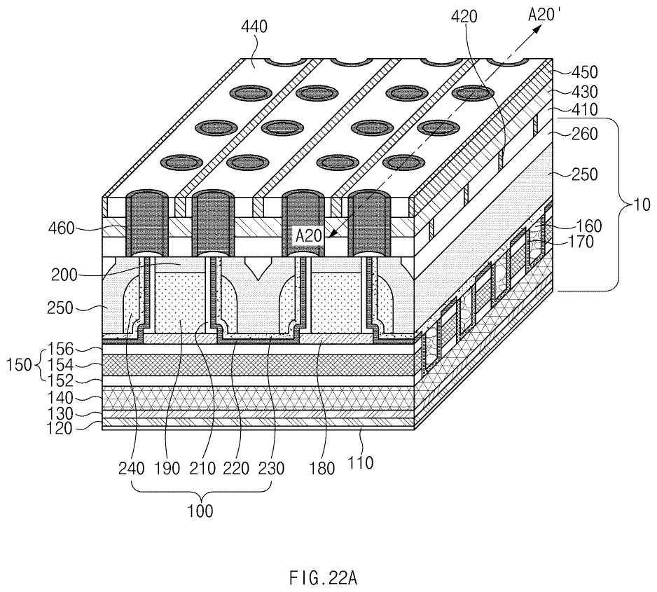

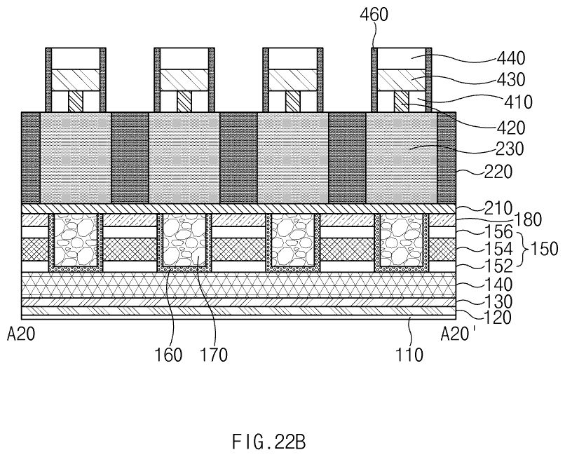

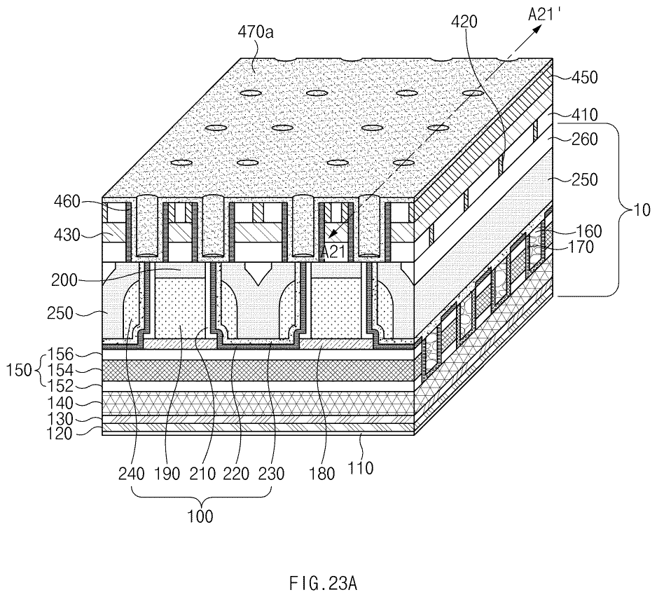

FIGS. 22A and 22B illustrate a process of selectively etching the semiconductor material layer 460a to form the second active region 460.

FIG. 22A is a perspective view illustrating a configuration of the semiconductor device in which the second active region 460 is formed.

FIG. 22B is a cross-sectional view illustrating a configuration of the semiconductor device taken along the twentieth cutting line (A20-A20′) of FIG. 22A.

Through the etching process, a semiconductor material layer 460a that contacts the sidewalls of the read wordline 440, the isolation insulation layer 430, and the read bitline 410 may selectively remain unused (or may be selectively left). At this time, the semiconductor material layer 460a that selectively remains unused may be referred to as an active region 460.

A second active region 460 may be formed by selectively etching the bottom surface and the top surface of the semiconductor material layer 460a. For example, the bottom surface and the top surface of the semiconductor material layer 460a may be selectively etched through a dry etching process.

The second active region 460 may be arranged spaced apart from the vertical portion of the first active region 220.

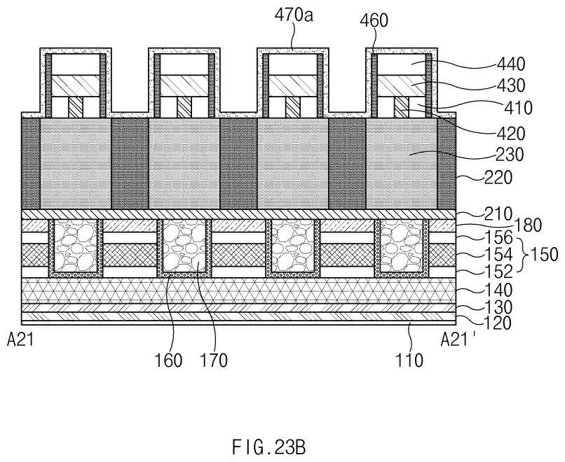

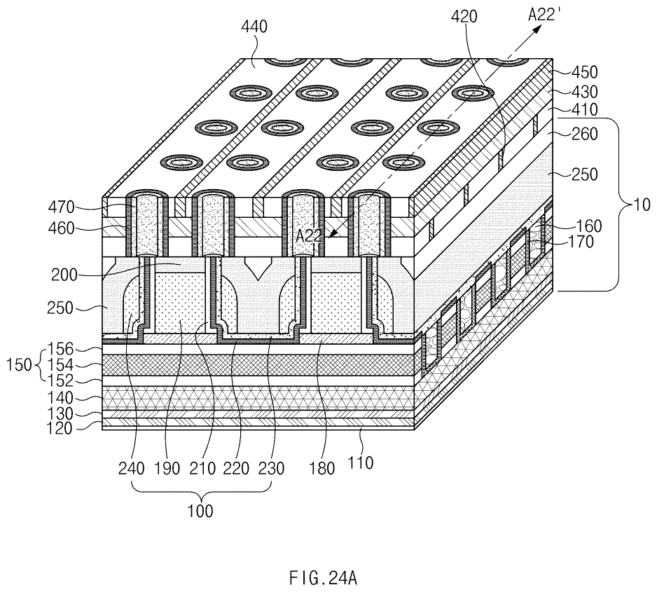

FIGS. 23A and 23B illustrate a process of forming the pre-storage gate insulation layer 470a that contacts the second active region 460.

FIG. 23A is a perspective view illustrating a configuration of the semiconductor device in which the pre-storage gate insulation layer 470a that contacts the active region 460 is formed.

FIG. 23B is a cross-sectional view illustrating a configuration of the semiconductor device taken along the 21st cutting line (A21-A21′) of FIG. 22A.

Referring to FIG. 23B, the pre-storage gate insulation layer 470a may include silicon oxide as an example.

The pre-storage gate insulation layer 470a may be formed to contact the side surface of the second active region 460. As shown in FIG. 23B, the pre-storage gate insulation layer 470a may also contact the top surfaces of the read wordlines 440 and the top surfaces of the first active regions 220.

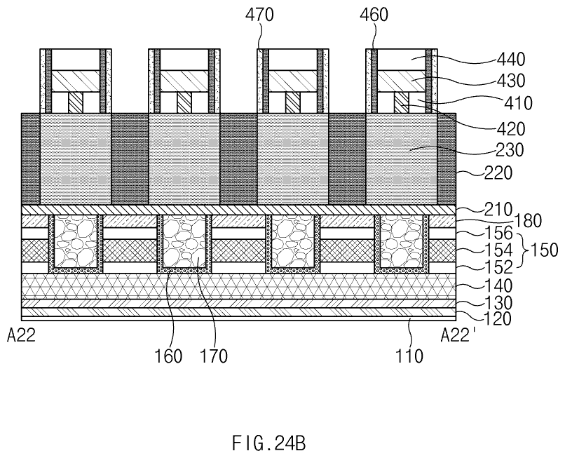

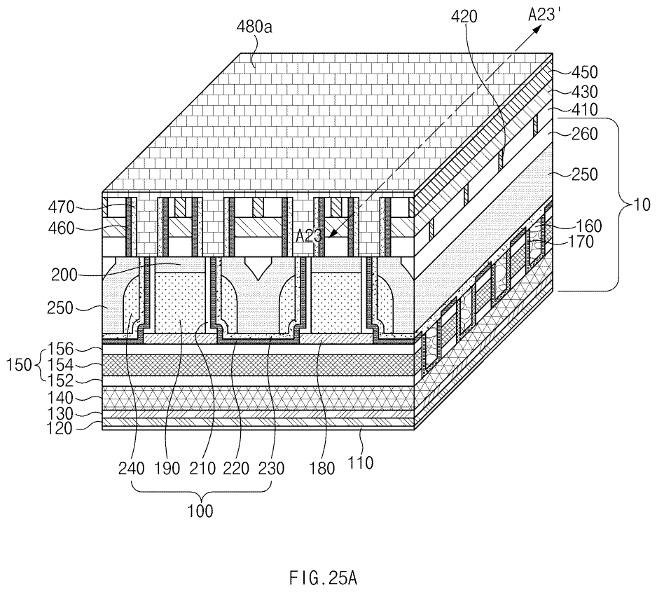

FIGS. 24A and 24B illustrate a process of selectively etching the pre-storage gate insulation layer 470a to form a storage gate insulation layer 470.

FIG. 24A is a perspective view illustrating a configuration of the semiconductor device in which the storage gate insulation layer 470 is formed.

FIG. 24B is a cross-sectional view illustrating a configuration of the semiconductor device taken along the 22^{nd} cutting line (A22-A22′) of FIG. 24A.

Referring to FIGS. 24A and 24B, a pre-storage gate insulation layer 470a contacting a sidewall of the second active region 460 may be selectively left through an etching process. At this time, the selectively left pre-storage gate insulation layer 470a may be referred to as the storage gate insulation layer 470. For example, the bottom surface and the top surface of the pre-storage gate insulation layer 470a may be selectively etched through a dry etching process.

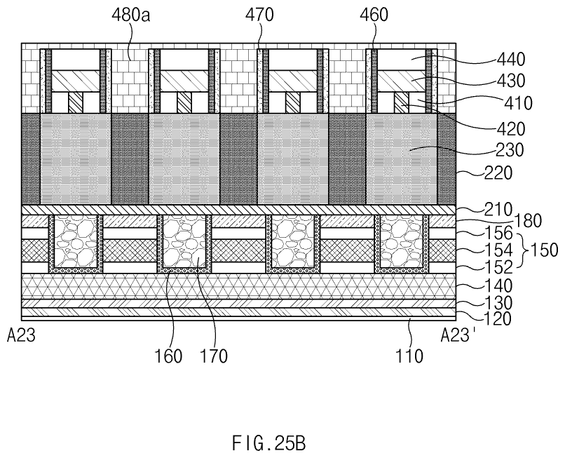

FIGS. 25A and 25B illustrate a process for forming the pre-storage gate 480a that contacts the storage gate insulation layer 470.

FIG. 25A is a perspective view illustrating a configuration of the semiconductor device in which the pre-storage gate 480a is formed.

FIG. 25B is a cross-sectional view illustrating a configuration of the semiconductor device taken along the 23^{rd} cutting line (A23-A23′) of FIG. 25A.

For example, the pre-storage gate 480a may include a metal, a metal mixture, a metal alloy, titanium nitride, tungsten, polysilicon, or a combination thereof. In an embodiment, the prestorage gate 480a may include titanium nitride as an example.

The pre-storage gate 480a may contact the storage gate insulation layer 470, and may fill at least a portion of the etched read wordline 440 and at least a portion of the etched read bitline 410.

The bottom surface of the pre-storage gate 480a may contact the vertical portion of the first active region 220.

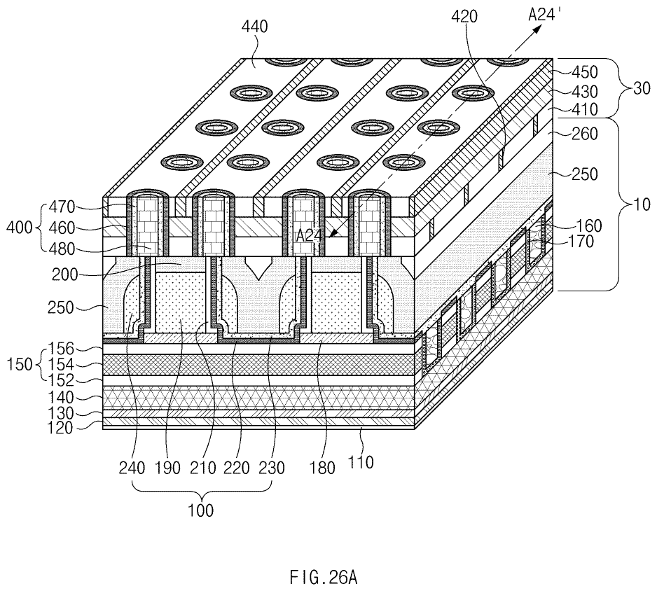

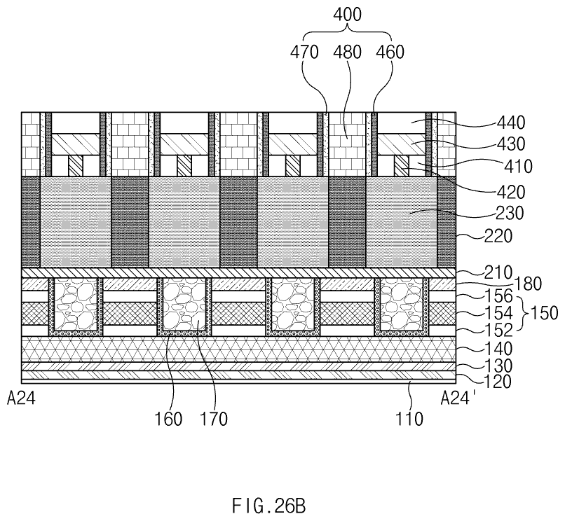

FIGS. 26A and 26B illustrate a process for selectively etching the pre-storage gate 480a to form the storage gate 480.

FIG. 26A is a perspective view illustrating a configuration of the semiconductor device in which the storage gate 480 is formed.

FIG. 26B is a cross-sectional view illustrating a configuration of the semiconductor device taken along the 24^{th} cutting line (A24-A24′) of FIG. 26A.

The bottom surface of the storage gate 480 may contact the vertical portion of the first active region 220. Each storage gate 480 may be disposed to be spaced apart from adjacent storage gates 480.

As is apparent from the above description, the semiconductor device based on an embodiment of the present disclosure includes a channel region having a vertical portion, so that the semiconductor device has a higher degree of integration.

The semiconductor device based on an embodiment of the present disclosure performs a multiply-accumulate (MAC) operation while having a storage transistor.

The embodiments of the present disclosure may provide a variety of advantageous effects capable of being directly or indirectly recognized by one of ordinary skill in the art.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in the present disclosure. Furthermore, the embodiments may be combined to form additional embodiments.

What is claimed is:

1. A semiconductor device comprising:
a first bitline extending in a first direction;
a first wordline extending in a second direction crossing the first direction;
a first active region contacting the first bitline;
a back-gate extending parallel to the first wordline; and
a storage transistor contacting the first active region,
wherein
the first active region is disposed between the first wordline and the back-gate, and includes a vertical portion extending in a third direction crossing the first and second directions and a horizontal portion that contacts one end of the vertical portion and the first bitline.

2. The semiconductor device according to claim 1, wherein the storage transistor includes:
a storage gate formed to contact another end of the vertical portion;
a storage gate insulation layer formed to overlap with the storage gate; and
a second active region formed to overlap with the storage gate insulation layer.

3. The semiconductor device according to claim 2, further comprising:
a second bitline extending in the first direction and contacting the second active region; and
a second wordline extending in the first direction and contacting the second active region.

4. The semiconductor device according to claim 3, wherein:
the second bitline contacts a plurality of second active regions which are arranged parallel to each other in the first direction; and
the second wordline contacts a plurality of second active regions arranged parallel to each other in the first direction.

5. The semiconductor device according to claim 3, further comprising:
an isolation insulation layer disposed between the second bitline and the second wordline and extending in the first direction.

6. The semiconductor device according to claim 2, wherein:
the storage gate includes a trench region that is disposed in the storage gate and extends in the third direction from one surface of the storage gate toward another other surface facing or opposite to the one surface;
the storage gate insulation layer overlaps with a sidewall and a bottom surface of the trench region; and
the second active region overlaps with the gate insulation layer.

7. The semiconductor device according to claim 1, wherein the storage transistor includes:
a storage gate contacting another end of the vertical portion;
a storage gate insulation layer surrounding a sidewall of the storage gate; and
a second active region surrounding the storage gate insulation layer,
wherein
the second active region contacts a second bitline extending in the first direction and a second wordline extending in the second direction.

8. The semiconductor device according to claim 7, wherein at least a portion of the second bitline overlaps with the second wordline.

9. The semiconductor device according to claim 7, further comprising:
an isolation insulation layer disposed over the second bitline,
wherein the second wordline is disposed over the isolation insulation layer.

10. The semiconductor device according to claim 7, wherein
the second bitline contacts a plurality of second active regions arranged parallel to each other in the first direction.

11. The semiconductor device according to claim 7, wherein
the second wordline contacts a plurality of second active regions which are arranged parallel to each other in the second direction.

12. The semiconductor device according to claim 7, wherein the second wordline surrounds at least a portion of the second active region.

13. The semiconductor device according to claim 7, wherein the second bitline surrounds at least a portion of the second active region.

14. A method for manufacturing a semiconductor device, the method comprising:
forming a first bitline extending in a first direction over a substrate;
forming a back-gate extending in a second direction crossing the first direction over the first bitline;
forming a first active region contacting the first bitline;
forming a first wordline extending in the second direction over the first bitline; and
forming a storage transistor contacting the first active region,
wherein
the first active region is disposed between the first wordline and the back-gate, and includes a vertical portion extending in a third direction crossing the first and second directions and a horizontal portion contacting one end of the vertical portion and the first bitline.

15. The method according to claim 14, wherein forming the storage transistor includes:
forming a storage gate contacting another end of the vertical portion;
forming a trench region that is disposed in the storage gate and extends in the third direction from one surface of the storage gate toward another surface facing or opposite to the one surface;
forming a storage gate insulation layer that overlaps bottom and side surfaces of the trench region; and
forming a second active region that overlaps with the storage gate insulation layer.

16. The method according to claim 15, further comprising:
forming an isolation insulation layer on the second active region;
forming a second bitline contacting the second active region within the isolation insulation layer; and
forming a second wordline that is isolated from the second bitline by the isolation insulation layer,
wherein the second bitline and the second wordline are formed to extend in the first direction.

17. The method according to claim 14, wherein forming the storage transistor includes:
forming a storage gate contacting another end of the vertical portion;
forming a storage gate insulation layer surrounding a sidewall of the storage gate; and
forming a second active region surrounding the storage gate insulation layer.

18. The method according to claim 17, further comprising:
forming a second bitline that extends in the first direction and surrounds at least a portion of the second active region;
forming an isolation insulation layer disposed over the second bitline; and
forming a second wordline that extends in the second direction and surrounds at least a portion of the second active region,
wherein
the second bitline is formed to overlap with at least a portion of the second wordline.

19. A semiconductor device comprising:
a write bitline extending in a first direction;
a write wordline extending in a second direction crossing the first direction;
a back-gate extending parallel to the write wordline;
a first active region that contacts the write bitline and extends between the write wordline and the back-gate;
a storage transistor contacting the first active region;
a read bitline extending in the first direction; and
a read wordline extending in the first direction,
wherein the storage transistor includes:
a storage gate that contacts the first active region and includes a trench region;
a storage gate insulation layer that overlaps with a sidewall and a bottom surface of the trench region; and
a second active region that overlaps with the storage gate insulation layer,
wherein
the second active region contacts the read bitline and the read wordline.

20. A semiconductor device comprising:
a write bitline extending in a first direction;
a write wordline extending in a second direction crossing the first direction;
a back-gate extending parallel to the write wordline;
a first active region that contacts the write bitline and extends between the write wordline and the back-gate;
a storage transistor that contacts the first active region;
a read bitline extending in the first direction; and
a read wordline extending in the second direction,
wherein the storage transistor includes:
a pillar-shaped storage gate that contacts the first active region;
a storage gate insulation layer that surrounds a sidewall of the storage gate; and
a second active region that surrounds the storage gate insulation layer,
wherein
the second active region contacts the read bitline and the read wordline.
